(19) United States
(12) Patent Application Publication
(10) Pub. No.: US 2017/0148732 A1
(43) Pub. Date: May 25, 2017

(54) SEMICONDUCTOR DEVICE

(71) Applicant: RENESAS ELECTRONICS CORPORATION, Tokyo (JP)

(72) Inventor: Teruhiro KUWAJIMA, Ibaraki (JP)

(21) Appl. No.: 15/333,750

(22) Filed: Oct. 25, 2016

(30) Foreign Application Priority Data
Nov. 19, 2015 (JP) 2015-226903

(51) Int. Cl. H01L 23/522; H01L 23/495; H01L 23/31; H01L 23/00; H01L 27/12

(52) U.S. Cl. CPC H01L 23/5227; H01L 23/5226; H01L 24/05; H01L 24/45; H01L 24/48; H01L 27/1203; H01L 23/3114; H01L 23/49513; H01L 23/49582; H01L 23/49555; H01L 23/4952; H01L 2224/04042; H01L 2224/05025; H01L 2224/4502; H01L 2224/4813; H01L 2924/13091; H01L 2224/45144; H01L 2224/45147

(57) ABSTRACT

An improvement is achieved in the performance of a semiconductor device. The semiconductor device includes a semiconductor substrate, a wiring structure formed over the semiconductor substrate and including a plurality of wiring layers, and a first coil, a second coil, and a third coil which are formed above the semiconductor substrate. In a region located under the first coil and overlapping the first coil in plan view, the second and third coils CL2a and CL2b are disposed. The second and third coils are foamed in the same layer and electrically coupled in series to each other. Each of the second and third coils and the first coil are not coupled to each other via a conductor, but are magnetically coupled to each other.

### CROSS-REFERENCE TO RELATED APPLICATIONS

The disclosure of Japanese Patent Application No. 2015-226903 filed on Nov. 19, 2015 including the specification, drawings and abstract is incorporated herein by reference in its entirety.

### BACKGROUND

The present invention relates to a semiconductor device and can be used appropriately for, e.g., a semiconductor device including a coil.

Examples of a technique which transmits an electric signal between two circuits to which electric signals having different potentials are input include a technique using a photocoupler. The photocoupler has a light emitting element such as a light emitting diode and a light receiving element such as a phototransistor. The photocoupler converts the electric signal input thereto to light in the light emitting element and returns the light to the electric signal in the light receiving element to thus transmit the electric signal.

Also, a technique which magnetically couples (inductively couples) two inductors to thus transmit an electric signal has been developed.

Each of Japanese Unexamined Patent Publications Nos. 2009-295804 (Patent Document 1), 2014-123671 (Patent Document 2), and 2013-115131 (Patent Document 3) discloses a technique related to a microtransformer.

### RELATED ART DOCUMENTS

### Patent Documents

[Patent Document 1] Japanese Unexamined Patent Publication No. 2009-295804

[Patent Document 2] Japanese Unexamined Patent Publication No. 2014-123671

[Patent Document 3] Japanese Unexamined Patent Publication No. 2013-115131

### SUMMARY

Examples of a technique which transmits an electric signal between two circuits to which electric signals having different potentials are input include a technique using a photocoupler. However, since the photocoupler has a light emitting element and a light receiving element, it is difficult to reduce the size thereof. In addition, when the frequency of the electric signal is high, the photocoupler cannot follow the electric signal, which limits the use of the photocoupler.

On the other hand, in a semiconductor device which transmits an electric signal using magnetically coupled inductors, the inductors can be formed using a microfabrication technique for the semiconductor device. Accordingly, it is possible to achieve a reduction in the size of the device and the electric characteristics of the device are excellent. Therefore, it is desired to promote the development of the semiconductor device.

As a result, even in such a semiconductor device including inductors, it is desired to maximally improve the performance thereof.

Other problems and novel features of the present invention will become apparent from a statement in the present specification and the accompanying drawings.

According to an embodiment, a semiconductor device includes a first coil, a second coil, and a third coil which are formed above a semiconductor substrate. In a region located under the first coil and overlapping the first coil in plan view, the second and third coils are disposed. The second and third coils are formed in the same layer and electrically coupled in series to each other. Each of the second and third coils and the first coil are not coupled to each other via a conductor, but are magnetically coupled to each other.

According to the embodiment, it is possible to improve the performance of the semiconductor device.

Alternatively, it is possible to reduce the size of the semiconductor device.

Still alternatively, it is possible to improve the performance of the semiconductor device and reduce the size of the semiconductor device.

### BRIEF DESCRIPTION OF THE DRAWINGS

FIG. 1 is a circuit diagram showing an example of an electronic device using a semiconductor device in a first embodiment;

FIG. 2 is an illustrative view showing an example of transmission of a signal;

FIG. 3 is a main-portion cross-sectional view of the semiconductor device in the embodiment;

FIG. 4 is a main-portion cross-sectional view of the semiconductor device in the embodiment;

FIG. 5 is a main-portion plan view of a semiconductor device in a first studied example;

FIG. 6 is a main-portion plan view of the semiconductor device in the first studied embodiment;

FIG. 7 is a main-portion cross-sectional view of the semiconductor device in the first studied example;

FIG. 8 is a main-portion plan view of a semiconductor device in a second studied example;

FIG. 9 is a main-portion plan view of the semiconductor device in the second studied embodiment;

FIG. 10 is a main-portion cross-sectional view of the semiconductor device in the second studied embodiment;

FIG. 11 is a circuit diagram showing a circuit configuration of a transformer formed in the semiconductor device in the second studied example;

FIG. 12 is a main-portion plan view of the semiconductor device in the embodiment;

FIG. 13 is a main-portion plan view of the semiconductor device in the embodiment;

FIG. 14 is a main-portion plan view of the semiconductor device in the embodiment;

FIG. 15 is a main-portion plan view of the semiconductor device in the embodiment;

FIG. 16 is a main-portion cross-sectional view of the semiconductor device in the embodiment;

FIG. 17 is a main-portion cross-sectional view of the semiconductor device in the embodiment;

FIG. 18 is a main-portion cross-sectional view of the semiconductor device in the embodiment;

FIG. 19 is a main-portion cross-sectional view of the semiconductor device in the embodiment;

FIG. 20 is a circuit diagram showing a circuit configuration of a transformer formed in the semiconductor device in the embodiment;

FIG. 21 is a main-portion plan view of the semiconductor device in the embodiment;

FIG. 22 is a main-portion plan view of the semiconductor device in the embodiment;

FIG. 23 is a main-portion plan view of the semiconductor device in the embodiment;

FIG. 24 is a main-portion plan view of the semiconductor device in the embodiment;

FIG. 25 is a main-portion plan view of the semiconductor device in the embodiment;

FIG. 26 is a main-portion plan view of the semiconductor device in the embodiment;

FIG. 27 is a main-portion plan view of the semiconductor device in the first studied example;

FIG. 28 is a main-portion plan view of the semiconductor device in the first studied example;

FIG. 29 is a main-portion plan view of the semiconductor device in the first studied example;

FIG. 30 is a main-portion plan view of the semiconductor device in the first studied example;

FIG. 31 is a main-portion cross-sectional view of the semiconductor device in the first studied example;

FIG. 32 is a main-portion plan view of a semiconductor device in a first modification;

FIG. 33 is a main-portion plan view of the semiconductor device in the first modification;

FIG. 34 is a main-portion plan view of a semiconductor device in a second modification;

FIG. 35 is a main-portion plan view of the semiconductor device in the second modification;

FIG. 36 is a cross-sectional view showing a semiconductor package in the embodiment;

FIG. 37 is a plan view showing an example of the chip layout of a semiconductor chip embedded in the semiconductor package in FIG. 36; and

FIG. 38 is a cross-sectional view showing a part of the semiconductor package in the embodiment.

### DETAILED DESCRIPTION

In the following embodiment, if necessary for the sake of convenience, the embodiment will be each described by being divided into a plurality of sections or embodiments. However, they are by no means irrelevant to each other unless particularly explicitly described otherwise, but are in relations such that one of the sections or embodiments is a modification, details, supplementary explanation, and so forth of part or the whole of the others. Also, in the following embodiment, when the number and the like (including the number, numerical value, amount, range, and the like) of elements are referred to, they are not limited to specific numbers unless particularly explicitly described otherwise or unless they are obviously limited to specific numbers in principle. The number and the like of the elements may be not less than or not more than specific numbers. Also, in the following embodiment, it goes without saying that the components thereof (including also elements, steps, and the like) are not necessarily indispensable unless particularly explicitly described otherwise or unless the components are considered to be obviously indispensable in principle. Likewise, if the shapes, positional relationships, and the like of the components and the like are referred to in the following embodiment, the shapes and the like are assumed to include those substantially proximate or similar thereto and the like unless particularly explicitly described otherwise or unless it can be considered that they obviously do not in principle. The same shall apply in regard to the foregoing numerical value and range.

The following will describe the embodiment in detail on the basis of the drawings. Note that, throughout all the drawings for illustrating the embodiment, members having the same functions are designated by the same reference numerals, and a repeated description thereof is omitted. Also, in the following embodiment, a description of the same or like parts will not be repeated in principle unless particularly necessary.

In the drawings used in the embodiment, hatching may be omitted even in a cross section for improved clarity of illustration, while even a plan view may be hatched for improved clarity of illustration.

### Embodiment

<About Circuit Configuration>

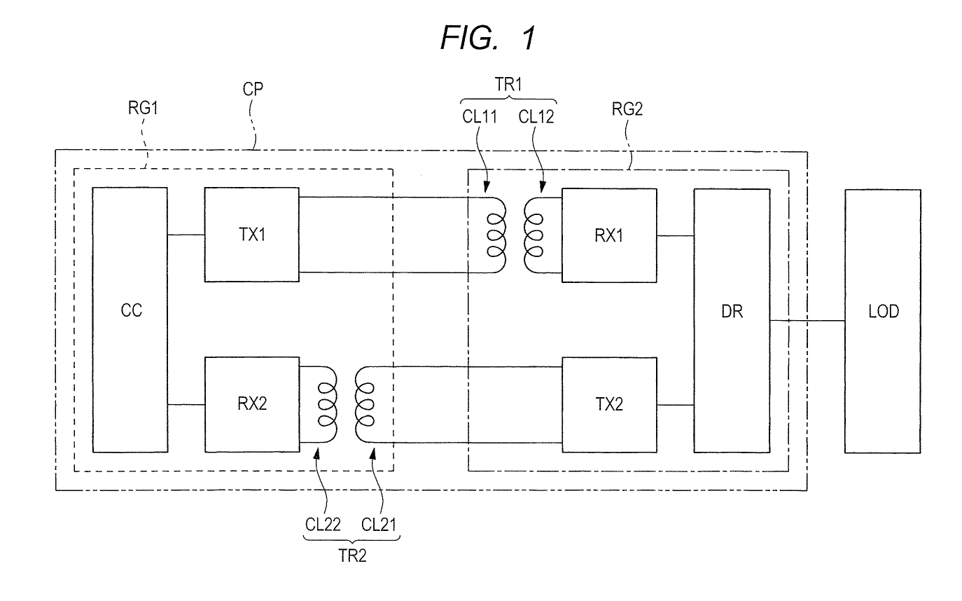

FIG. 1 is a circuit diagram showing an example of an electronic device (semiconductor device) using a semiconductor device (semiconductor chip) in the embodiment. Note that, in FIG. 1, the part enclosed by the dotted line is formed in a semiconductor chip CP.

The electronic device shown in FIG. 1 includes the semiconductor chip CP. From another perspective, the electronic device shown in FIG. 1 includes a semiconductor package in which the semiconductor chip CP is embedded.

As shown in FIG. 1, in the semiconductor chip CP, a control circuit CC, a transmission circuit TX1, a transmission circuit TX2, a reception circuit RX1, a reception circuit RX2, and a control circuit (drive circuit) DR are formed.

The transmission circuit TX1 and the reception circuit RX1 are circuits for transmitting a signal (control signal) from the control circuit CC to the control circuit DR. On the other hand, the transmission circuit TX2 and the reception circuit RX2 are circuits for transmitting a signal from the control circuit DR to the control circuit CC. The control circuit CC controls or drives the control circuit DR. The control circuit DR controls or drives a load LOD. For example, the control circuit DR controls or drives a switch (switching element) for the load LOD to switch the switch and thus allow the load LOD to be driven. The control circuit DR can also be regarded as a drive circuit. The load LOD is provided outside the semiconductor chip CP. From another perspective, the load LOD is provided outside the semiconductor package in which the semiconductor chip CP is embedded. As the load LOD, there are various loads depending on the application thereof. For example, a motor or the like can be shown as an example of the load LOD.

The semiconductor chip CP has a lower-voltage circuit region RG1 and a higher-voltage circuit region RG2. That is, the main surface of the semiconductor chip CP has the lower-voltage circuit region RG1 and the higher-voltage circuit region RG2, though a detailed description thereof will be given later. The lower-voltage circuit region RG1 and the higher-voltage circuit region RG2 are electrically isolated from each other by an isolation region 2 formed in the semiconductor chip CP and described later. In FIG. 1, the portion enclosed by the one-dot-dash line is formed in the lower-voltage circuit region RG1 and the portion enclosed by the two-dot-dash line is famed in the higher-voltage circuit region RG2. Among the control circuit CC, the transmission circuits TX1 and TX2, the reception circuits RX1 and RX2, and the control circuit DR, the control circuit CC, the transmission circuit TX1, and the reception circuit RX2 are foamed in the lower-voltage circuit region RG1 of the semiconductor chip CP, and the control circuit DR, the transmission circuit TX2, and the reception circuit RX1 are foamed in the higher-voltage circuit region RG2 of the semiconductor chip CP.

Between the transmission circuit TX1 and the reception circuit RX1, a transformer (Xformer, converter, magnetically coupled element, or electromagnetically coupled element) TR1 including magnetically coupled (inductively coupled) coils (inductors) CL11 and CL12 is interposed. From the transmission circuit TX1 to the reception circuit RX1, a signal can be transmitted via the transformer TR1 (i.e., via the magnetically coupled coils CL11 and CL12). This allows the reception circuit RX1 to receive the signal transmitted from the transmission circuit TX1. As a result, the control circuit CC can transmit a signal (control signal) to the control circuit DR via the transmission circuit TX1, the transformer TR1, and the reception circuit RX1. The transformer TR1 (coils CL11 and CL12) is formed in the higher-voltage circuit region RG2 of the semiconductor chip CP. Each of the coils CL11 and CL12 can also be regarded as an inductor. The transformer TR1 can also be regarded as a magnetically coupled element.

On the other hand, between the transmission circuit TX2 and the reception circuit RX2, a transformer (Xformer, converter, magnetically coupled element, or electromagnetically coupled element) TR2 including magnetically coupled (inductively coupled) coils (inductors) CL21 and CL22 is interposed. From the transmission circuit TX2 to the reception circuit RX2, a signal can be transmitted via the transformer TR2 (i.e., via the magnetically coupled coils CL21 and CL22). This allows the reception circuit RX2 to receive the signal transmitted from the transmission circuit TX2. As a result, the control circuit DR can transmit a signal to the control circuit CC via the transmission circuit TX2, the transformer TR2, and the reception circuit RX2. The transformer TR2 (coils CL21 and CL22) are faulted in the lower-voltage circuit region RG1 of the semiconductor chip CP. Each of the coils CL21 and CL22 can also be regarded as an inductor. The transformer TR2 can also be regarded as a magnetically coupled element.

The transformer TR1 is formed of the coils CL11 and CL12 formed in the higher-voltage circuit region RG2 of the semiconductor chip CP. The coils CL11 and CL12 are not connected via a conductor, but are magnetically coupled to each other. As a result, when a current flows in the coil CL11, an induced electromotive force is generated in the coil CL12 in accordance with a change in the current and an induced current flows therein. The coil CL11 is a primary coil, while the coil CL12 is a secondary coil. By using this, a signal is sent from the transmission circuit TX1 to the coil CL11 (primary coil) of the transformer TR1 to cause a current to flow. In response to this, an induced current (or induced electromotive force) is generated in the coil CL12 (secondary coil) of the transformer TR1. The reception circuit RX1 senses (receives) the generated induced current to be able to receive a signal corresponding to the signal sent from the transmission circuit TX1.

The transformer TR2 is formed of the coils CL21 and CL22 formed in the lower-voltage circuit region RG1 of the semiconductor chip CP. The coils CL21 and CL22 are not connected via a conductor, but are magnetically coupled. As a result, when a current flows in the coil CL21, an induced electromotive force is generated in the coil CL22 in accordance with a change in the current and an induced current flows therein. The coil CL21 is a primary coil, while the coil CL22 is a secondary coil. By using this, a signal is sent from the transmission circuit TX2 to the coil CL21 (primary coil) of the transformer TR2 to cause a current to flow. In response to this, an induced current (or induced electromotive force) is generated in the coil C22 (secondary coil) of the transformer TR2. The reception circuit RX2 senses (receives) the generated induced current to be able to receive a signal corresponding to the signal sent from the transmission circuit TX2.

Using a path extending from the control circuit CC to the control circuit DR via the transmission circuit TX1, the transformer TR1, and the reception circuit RX1 and a path extending from the control circuit DR to the control circuit CC via the transmission circuit TX2, the transformer TR2, and the reception circuit RX2, a signal is transmitted/received between the control circuit CC in the lower-voltage circuit region RG1 of the semiconductor chip CP and the control circuit DR in the higher-voltage circuit region RG2 of the semiconductor chip CP. That is, through the reception of the signal transmitted from the transmission circuit TX1 by the reception circuit RX1 and through the reception of the signal transmitted from the transmission circuit TX2 by the reception circuit RX2, the signal can be transmitted/received between the control circuit CC in the lower-voltage circuit region RG1 of the semiconductor chip CP and the control circuit DR in the higher-voltage circuit region RG2 of the semiconductor chip CP. As described above, the signal transmission from the transmission circuit TX1 to the reception circuit RX1 is performed via the transformer TR1 (i.e., magnetically coupled coils CL11 and CL12), and the signal transmission from the transmission circuit TX2 to the reception circuit RX2 is performed via the transformer TR2 (i.e., magnetically coupled coils CL21 and CL22). The control circuit DR can control or drive the load LOD in accordance with the signal transmitted from the control circuit CC (i.e., signal transmitted from the transmission circuit TX1 to the reception circuit RX1 via the transformer TR1).

The lower-voltage circuit region RG1 and the higher-voltage circuit region RG2 of the semiconductor chip CP have different voltage levels (reference potentials). That is, the circuits (which are the control circuit CC, the transmission circuit TX1, and the reception circuit RX2 herein) formed in the lower-voltage circuit region RG1 of the semiconductor chip CP and the circuits (which are the control circuit DR, the transmission circuit TX2, and the reception circuit RX1 herein) formed in the higher-voltage circuit region RG2 of the semiconductor chip CP have different voltage levels (reference potentials).

For example, the control circuit DR drives the load LOD such as a motor. Specifically, the control circuit DR drives or controls the switch (switching element) of the load LOD such as a motor to switch the switch. Accordingly, when the target switch to be driven is turned ON, the reference potential (voltage level) of the control circuit DR may rise to a voltage substantially equivalent to the power supply voltage (operation voltage) of the target switch to be driven, which is considerably high (e.g., about several hundreds of volts to several thousands of volts). Consequently, a large difference is produced between the respective voltage levels (reference potentials) of the control circuits CC and DR. Specifically, when the target switch to be driven is ON, a voltage (e.g., about several hundreds of volts to several thousands of volts) higher than the power supply voltage (e.g., about several volts to several tens of volts) supplied to the control circuit CC is supplied to the control circuit DR.

However, since the signal transmission between the control circuits CC and DR is performed via the transformer s TR1 and TR2, signal transmission between different-voltage circuits is possible. Specifically, what is electrically transmitted between the controls circuits CC and DR is only the signal transmitted by electromagnetic induction via the transformer TR1 or only the signal transmitted by electromagnetic induction via the transformer TR2. Accordingly, even when the voltage level (reference potential) of the control circuit CC and the voltage level (reference potential) of the control circuit DR are different, it is possible to reliably prevent the voltage level (reference potential) of the control circuit DR from being input to the control circuit CC or prevent the voltage level (reference potential) of the control circuit CC from being input to the control circuit DR. That is, even when the target switch to be driven is turned ON and the reference potential (voltage level) of the control circuit DR rises to a high voltage substantially equivalent to the power supply voltage (e.g., about several hundreds of volts to several thousands of volts) of the target switch to be driven, it is possible to reliably prevent the high voltage from being input to the control circuit CC. This allows an electric signal to be reliably transmitted between the control circuits CC and DR having different voltage levels (reference potentials).

As a result, in each of the transformer s TR1 and TR2, a large potential difference may be produced between the primary and secondary coils. Conversely, since a large potential difference may be produced, the primary and secondary coils which are not connected via a conductor but are magnetically coupled are used for signal transmission. Therefore, in forming the transformer s TR1 and TR2 in the semiconductor chip CP, it is important to maximize the dielectric breakdown voltage between the primary and secondary coils in terms of improving the reliability of the semiconductor chip CP, a semiconductor package in which the semiconductor chip CP is embedded, or an electronic device using the semiconductor package.

Note that, in the case shown in FIG. 1, the control circuit CC is embedded in the semiconductor chip CP. However, in another foam, it is also possible to embed the control circuit CC in a semiconductor chip other than the semiconductor chip CP. In the case shown in FIG. 1, the control circuit DR is embedded in the semiconductor chip CP. However, in another form, it is also possible to embed the control circuit DR in a semiconductor chip other than the semiconductor chip CP.

<About Example of Signal Transmission>

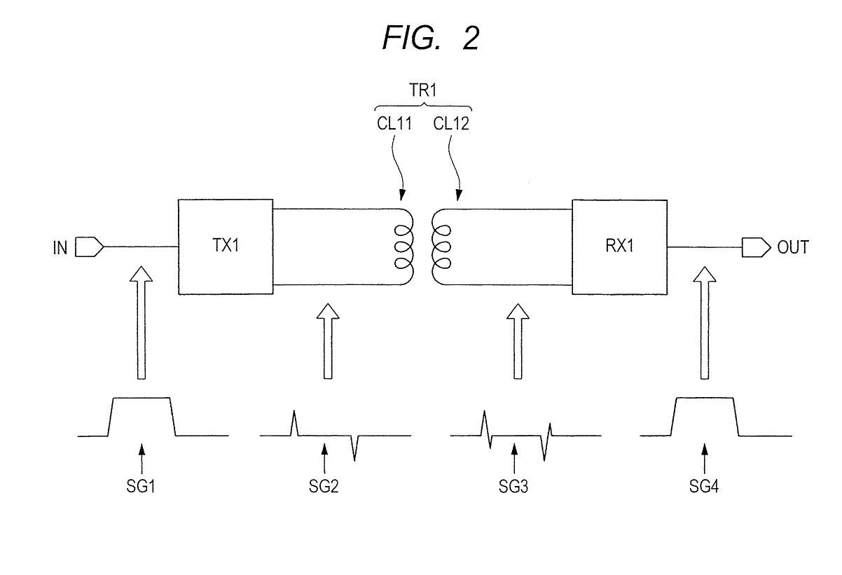

FIG. 2 is an illustrative view showing an example of signal transmission.

The transmission circuit TX1 modulates a square-wave signal SG1 input to the transmission circuit TX1 to a differential-wave signal SG2 and sends the differential-wave signal SG2 to the coil CL11 (primary coil) of the transformer TR1. When a current resulting from the differential-wave signal SG2 flows in the coil CL11 (primary coil) of the transformer TR1, a signal SG3 corresponding to the current flows in the coil CL12 (secondary coil) of the transformer TR1 due to an induced electromotive force. By amplifying the signal SG3 and further modulating the amplified signal SG3 into a square wave in the reception circuit RX2, a square-wave signal SG4 is output from the reception circuit RX2. Thus, the signal SG4 corresponding to the signal SG1 input to the transmission circuit TX1 can be output from the reception circuit RX2. In this manner, a signal is transmitted from the transmission circuit TX1 to the reception circuit RX1. Signal transmission from the transmission circuit TX2 to the reception circuit RX2 can also be similarly performed.

FIG. 2 shows an example of the signal transmission from the transmission circuit to the reception circuit, but the signal transmission is not limited thereto and can variously be modified. Any method may be used appropriately as long as the method transmits a signal via magnetically coupled coils (primary and secondary coils).

<About Structure of Semiconductor Chip>

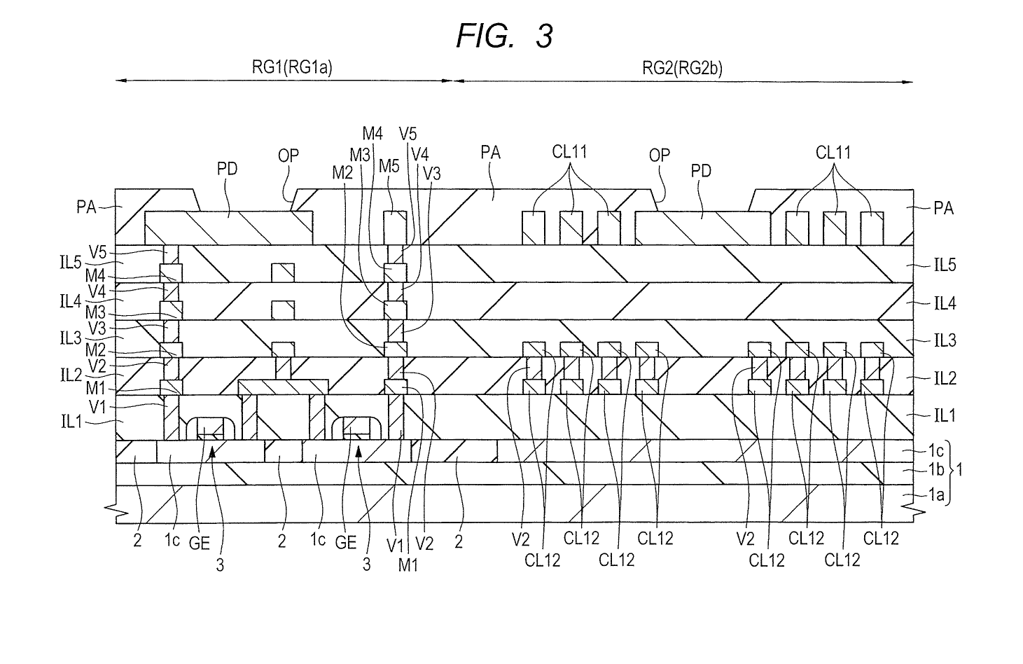

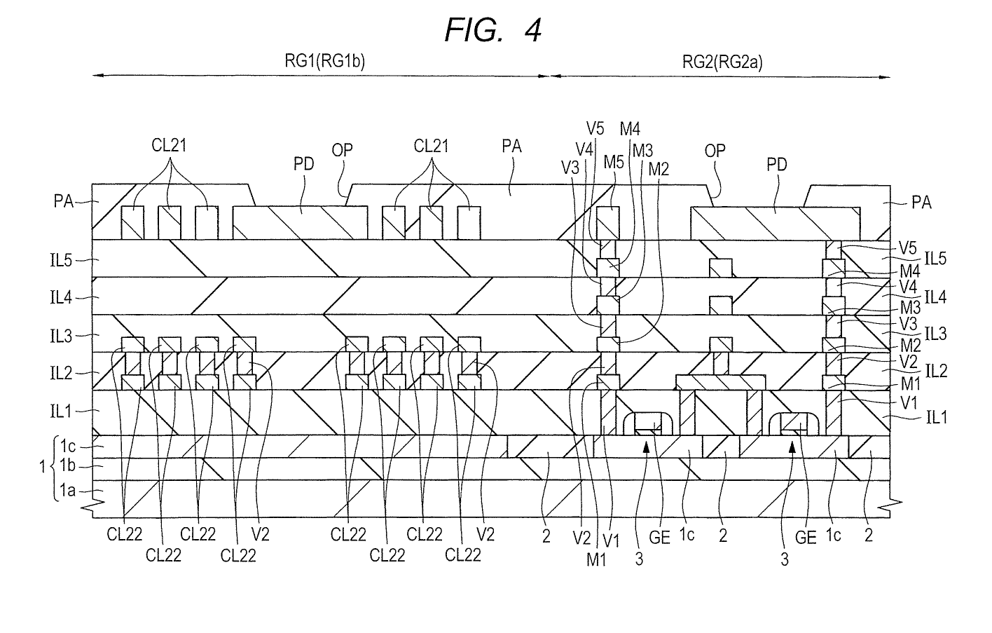

FIGS. 3 and 4 are main-portion cross-sectional views showing a cross-sectional structure of the semiconductor device (semiconductor chip CP) in the present embodiment.

The semiconductor device in the present embodiment is formed using a SOI (Silicon on Insulator) substrate and has the lower-voltage circuit region RG1 and the higher-voltage circuit region RG2. Note that the lower-voltage circuit region RG1 and the higher-voltage circuit region RG2 correspond to the different two-dimensional regions of the main surface of the same SOI substrate 1. The lower-voltage circuit region RG1 includes a peripheral circuit formation region RG1a and a transformer formation region RG1b. The higher-voltage circuit region RG2 includes a peripheral circuit formation region RG2a and a transformer formation region RG2b. The transformer formation region RG1b corresponds to the region (two-dimensional region) of the lower-voltage circuit region RG1 where the foregoing transformer TR2 is formed. The peripheral circuit formation region RG1a corresponds to the region (two-dimensional region) of the lower-voltage circuit region RG1 where the foregoing control circuit CC, the foregoing transmission circuit TX1, and the foregoing reception circuit RX2 are formed. The transformer formation region RG2b corresponds to the region (two-dimensional region) of the higher-voltage circuit region RG2 where the foregoing transformer TR1 is formed. The peripheral circuit to/motion region RG2a corresponds to the region (two-dimensional region) of the higher-voltage circuit region RG2 where the foregoing control circuit DR, the foregoing transmission circuit TX2, and the foregoing reception circuit RX1 are formed. FIG. 3 shows a cross section traversing the peripheral circuit formation region RG1a of the lower-voltage circuit region RG1 and the transformer to/motion region RG2b of the higher-voltage circuit region RG2. FIG. 4 shows a cross section traversing the transformer formation region RG1b of the lower-voltage circuit region RG1 and the peripheral circuit formation region RG2a of the higher-voltage circuit region RG2.

The SOI substrate 1 has a substrate (semiconductor substrate or supporting substrate) 1a made of monocrystalline silicon or the like as a supporting substrate, an insulating layer (embedded insulating film, embedded oxide film, or BOS (Buried Oxide) layer) 1b famed over the main surface of the substrate la and made of silicon dioxide or the like, and a semiconductor layer (SOI layer) 1c formed over the upper surface of the insulating layer 1b and made of monocrystalline silicon or the like. The substrate 1a is the supporting substrate supporting the insulating layer 1b and the structure located thereabove. The substrate 1a, the insulating layer 1b, and the semiconductor layer 1c form the SOI substrate 1. Since the SOI substrate 1 has the semiconductor layer 1c in the uppermost layer thereof and a semiconductor element such as a MISFET is formed in the semiconductor layer 1c, the SOI substrate 1 can be regarded as a type of semiconductor substrate.

As shown in FIGS. 3 and 4, in the SOI substrate 1 included in the semiconductor device (semiconductor chip CP) in the present embodiment, semiconductor elements such as a MISFET (Metal Insulator Semiconductor Field Effect Transistor) are famed. The semiconductor elements are formed in the peripheral circuit formation regions RG1a and RG2a.

In the SOI substrate 1, the isolation regions 2 are formed. The isolation regions 2 are formed of an insulator (e.g., silicon dioxide) embedded in isolation trenches. The isolation regions 2 extend through the semiconductor layer 1c of the SOI substrate 1. The semiconductor layer 1c in the lower-voltage circuit region RG1 and the semiconductor layer 1c in the higher-voltage circuit region RG2 are electrically isolated from each other by the isolation region 2.

In the peripheral circuit formation regions RG1a and RG2a, in the main surface of the SOI substrate 1, semiconductor elements such as a MISFET (Metal Insulator Semiconductor Field Effect Transistor) 3 are foamed. The MISFET 3 has a gate electrode GE formed over the semiconductor layer 1c via a gate insulating film. In the regions of the semiconductor layer 1c which are located on both sides of the gate electrode GE, the source/drain regions of the MISFET 3 are faulted.

The description has been given herein using the MISFETs as an example of the semiconductor elements formed in the peripheral circuit formation regions RG1a and RG2a. However, it may also be possible to form capacitive elements, resistive elements, memory elements, transistors having other configurations, or the like instead of the MISFETs in the peripheral circuit formation regions RG1a and RG2a. The semiconductor elements formed in the peripheral circuit formation region RG1a form the foregoing control circuit CC, the transmission circuit TX1, and the reception circuit RX2. The semiconductor elements faulted in the peripheral circuit formation region RG2a form the foregoing control circuit DR, the reception circuit RX1, and the transmission circuit TX2.

The description has been given herein using the SOI substrate 1 as an example of the semiconductor substrate included in the semiconductor chip CP. However, in another faun, it is also possible to use a monocrystalline silicon substrate or the like as the semiconductor substrate included in the semiconductor chip CP. That is, instead of the SOI substrate 1, a semiconductor substrate such as a monocrystalline silicon substrate can also be used.

Over the SOI substrate 1, a wiring structure (multilayer wiring structure) including a plurality of wiring layers is formed. The wiring structure is formed of a plurality of interlayer insulating films and the plurality of wiring layers.

That is, over the SOI substrate 1, a plurality of interlayer insulating films IL1, IL2, IL3, IL4, and IL5, plugs (via portions) V1, via portions V2, V3, V4, and V5, and wires M1, M2, M3, M4, and M5 are formed.

Specifically, over the SOI substrate 1, the interlayer insulating film IL1 is formed as an insulating film so as to cover the foregoing MISFETs 3. Over the interlayer insulating film IL1, the wires M1 are formed. The wires M1 are in the first wiring layer (lowermost wiring layer). Over the interlayer insulating film IL1, the interlayer insulating film IL2 is formed as an insulating film so as to cover the wires M1. Over the interlayer insulating film IL2, the wires M2 are formed. The wires M2 are in the second wiring layer as the wiring layer immediately above the first wiring layer. Over the interlayer insulating film IL2, the interlayer insulating film IL3 is formed as an insulating film so as to cover the wires M2. Over the interlayer insulating film IL3, the wires M3 are formed. The wires M3 are in the third wiring layer as the wiring layer immediately above the second wiring layer. Over the interlayer insulating film IL3, the interlayer insulating film IL4 is formed as an insulating film so as to cover the wires M3. Over the interlayer insulating film IL4, the wires M4 are formed. The wires M4 are in the fourth wiring layer as the wiring layer immediately above the third wiring layer. Over the interlayer insulating film IL4, the interlayer insulating film IL5 is formed as an insulating film so as to cover the wires M4. Over the interlayer insulating film IL5, the wires M5 are formed. The wires M5 are in the fifth wiring layer as the wiring layer immediately above the fourth wiring layer. Each of the wires M1, M2, M3, M4, and M5 is the internal wiring of the semiconductor device (semiconductor chip CP).

The plugs V1 are made of a conductor and formed in a layer below the wires Ml. That is, the plugs V1 are formed in the interlayer insulating film IL1 so as to extend through the interlayer insulating film IL1 and electrically coupled to the wires M1 with the upper surfaces thereof being in contact with the lower surfaces of the wires M1. The bottom portions of the plugs V1 are coupled to the various semiconductor regions (such as, e.g., the source/drain regions of the MISFETs 3) formed in the SOI substrate 1, the gate electrodes GE, and the like. Thus, the wires M1 are electrically coupled to the various semiconductor regions formed in the SOI substrate 1, the gate electrodes BE, and the like via the plugs V1.

The via portions V2 are made of a conductor and formed between the wires M2 and M1, i.e., in the interlayer insulating film IL2 to couple the wires M2 and M1 to each other. The via portions V2 can also be formed integrally with the wires M2. The via portions V3 are made of a conductor and formed between the wires M3 and M2, i.e., in the interlayer insulating film IL3 to couple the wires M3 and M2 to each other. The via portions V3 can also be formed integrally with the wires M3. The via portions V4 are made of a conductor and formed between the wires M4 and M3, i.e., in the interlayer insulating film IL4 to couple the wires M4 and M3 to each other. The via portions V4 can also be faulted integrally with the wires M4. The via portions V5 are made of a conductor and formed between the wires M5 and M4, i.e., in the interlayer insulating film IL5 to couple the wires M5 and M4 to each other. The via portions V5 can also be formed integrally with the wires M5.

Each of the wires M1, M2, M3, M4, and M5 can be foisted using a method which patterns the conductive film formed over the interlayer insulating film or a method (so-called damascene method) which embeds a conductive film in the trenches formed in the interlayer insulating film.

The wires in the fifth wiring layer, i.e., the wires M5 are the uppermost wires. That is, the first wiring layer (wires M1), the second wiring layer (wires M2), the third wiring layer (wires M3), the fourth wiring layer (wires M4), and the fifth wiring layer (wires M5) have achieved intended wiring of the semiconductor elements (e.g., the foregoing MISFETs 3) formed in the SOI substrate 1 and allow each of the semiconductor elements to perform an intended operation.

Pads (pad electrodes or bonding pads) PD are faulted of the fifth wiring layer including the uppermost-layer wires. In other words, the pads PD are formed in the same layer as that of the wires M5. That is, the wires M5 and the pads PD are formed of the same conductive layer in the same process step. Consequently, the pads PD are formed over the interlayer insulating film IL5. The pads PD can also be regarded as parts of the wires M5 but, in contrast to the wires M5 covered with a protective film PA, each of the pads PD has at least a part thereof exposed from each of openings OP of the protective film PA.

Note that, in the case shown in FIGS. 3 and 4, the number of the wiring layers formed over the SOI substrate 1 is 5 (the total of five layers respectively include the wires M1, M2, M3, M4, and M5), but the number of the wiring layers is not limited to 5 and can variously be changed.

In the transformer formation region RG2b of the higher-voltage circuit region RG2, the primary coil (coil CL11) and the secondary coil (coil CL12) of the transformer TR1 are formed above the SOI substrate 1. The coils CL11 and CL12 are not formed in the same layer, but are formed in different layers. Between the coils CL11 and CL12, one or more insulating layers are interposed. The coils CL11 as the primary coil are formed over the coils CL12 as the secondary coil. The coils CL12 faulted in the lower layer are not in contact with the SOI substrate 1. Between the coils CL12 and the SOI substrate 1, one or more insulating layers are interposed.

Referring to FIG. 3, a more specific description will be given below of the coils CL11 and CL12.

The coils CL11 and CL12 are respectively formed of any two of the plurality of wiring layers formed over the SOI substrate 1. That is, the coils CL11 and CL12 are famed in the same layers as those of any two of the wires M1, M2, M3, M4, and M5. Note that the wiring layer in which the coils CL11 are famed is different from the wiring layer in which the coils CL12 are formed. Since the coils CL11 as the primary coil are formed over the coils CL12 as the secondary coil, the coils CL11 are formed of the wiring layer located above the wiring layer of which the coils CL12 are foamed.

In the case shown in FIG. 3, the coils CL11 are formed of th fifth wiring layer, while the coils CL12 are formed of the first and second wiring layers. That is, the coils CL1 are formed in the same layer as that of the wires M5, while the coils CL12 are famed in the same layers as those of the wires M1 and M2.

The coils CL11 as the primary coil are formed of the one wiring layer. The coils CL11 can also be formed of the wiring layer located below the uppermost wiring layer, but is more preferably formed of the uppermost wiring layer (which is the fifth wiring layer herein). This can increase the space between the coils CL11 and CL12 and thus increase the dielectric breakdown voltage between the coils CL11 and CL12.

Each of the coils CL12 as the secondary coil is formed of the two wiring layers. The coil CL12 can also be formed of the second and third wiring layers or the third and fourth wiring layers, but is more preferably formed of the first and second wiring layers. By foaming each of the coils CL12 as the secondary coil of the first and second wiring layers, it is possible to increase the space between the coils CL11 and CL12 and thus increase the dielectric breakdown voltage between the coils CL11 and CL12.

In the case where each of the coils CL11 is formed of the fifth wiring layer, the coil CL11 can be formed of the conductive layer in the same layer as that of the wires M5 and the pads PD in the same step of forming the wires M5 and the pads PD. In the case of, e.g., forming the wires M5 and the pads PD by patterning the conductive film formed over the interlayer insulating film IL5, the wires M5, the pads PD, and the coils CL11 can be formed by patterning the conductive film.

In the case where each of the coils CL12 is formed of the first and second wiring layers, the portion of the coil CL12 which is formed of the first wiring layer can be formed of the conductive layer in the same layer as that of the wires M1 in the same step of forming the wires M1, and the portion of the coil CL12 which is formed of the second wiring layer can be faulted of the conductive layer in the same layer as that of the wires M2 in the same step of forming the wires M2. In the case of forming the wires M1 by, e.g., patterning the conductive film formed over the interlayer insulating film IL1, the wires M1 and the portions of the coils CL12 which are formed in the first wiring layer (corresponding to coil wires CW2 described later) can be formed by patterning the conductive film. In the case of forming the wires M2 by patterning the conductive film formed over the interlayer insulating film IL2, the wires M2 and the portions of the coils CL12 which are formed in the second wiring layer (corresponding to coil wires CW3 described later) can be formed by patterning the conductive film.

Between the coils CL12 and CL11, one or more insulating layers are interposed. For example, in the case where the coils CL11 are each formed of the fifth wiring layer and the coils CL12 are each faulted of the first and second wiring layers, the interlayer insulating films (i.e., interlayer insulating films IL3, IL4, and IL5) in the layers located above the second wiring layer and below the fifth wiring layer are interposed between the coils CL11 and CL12. Consequently, the coils CL11 and CL12 are not connected via a conductor, but are in an electrically insulated state. However, as described above, the coils CL11 and CL12 are magnetically coupled to each other.

In the transformer formation region RG1b of the lower-voltage circuit region RG1, the primary coil (coils CL21) and the secondary coil (coils CL22) of the transformer TR2 are formed above the SOI substrate 1. The coils CL21 are formed in the same layer as that of the coils CL11, while the coils CL22 are formed in the same layer as that of the coils CL12. In the transformer formation region RG1b of the lower-voltage circuit region RG1, the coils CL21 are formed above the coils CL22. The configuration of the coils CL21 and CL22 is the same as the configuration of the coils CL11 and CL12 except that the coils CL21 and CL22 are formed not in the transformer formation region RG2b of the higher-voltage circuit region RG2, but in the transformer formation region RG1b of the lower-voltage circuit region RG1. Therefore, a repeated description thereof is omitted herein.

In the uppermost layer of the semiconductor chip CP, the insulating protective film (surface protective film) PA is formed. The protective film PA covers and protects the wires M5 and the coils CL11 and CL21. That is, the protective film PA is formed over the interlayer insulating film IL5 so as to cover the wires M5, the pads PD, and the coils CL11 and CL21. The protective film PA can be formed of, e.g., a resin film such as a polyimide resin. Note that each of the pads PD has at least a part thereof exposed from the opening OP of the protective film PA.

In the lower-voltage circuit region RG1 of the semiconductor chip CP, the foregoing control circuit CC, the foregoing transmission circuit TX1, the foregoing reception circuit RX2, and the coils CL21 and CL22 are formed. In the higher-voltage circuit region RG2 of the semiconductor chip CP, the foregoing reception circuit RX1, the foregoing transmission circuit TX2, the foregoing control circuit DR, and the coils CL11 and CL12 are formed.

The transmission circuit TX1 formed in the semiconductor chip CP is electrically coupled to the coils CL11 via the internal wiring (wiring in one or more layers including the wires M5) of the semiconductor chip CP and via a wire BW1 described later. The reception circuit RX1 formed in the semiconductor chip CP is electrically coupled to the coils CL12 via the internal wiring of the semiconductor chip CP. This allows a signal to be transmitted from the transmission circuit TX1 to the reception circuit RX1 via the coils CL11 and CL12.

The transmission circuit TX2 famed in the semiconductor chip CP is electrically coupled to the coils CL21 via the internal wiring (wiring in one or more layers including the wires M5) of the semiconductor chip CP and the wires BW1 described later. The reception circuit RX2 formed in the semiconductor chip CP is electrically coupled to the coils CL22 via the internal wiring of the semiconductor chip CP. This allows a signal to be transmitted from the transmission circuit TX2 to the reception circuit RX2 via the coils CL21 and CL22.

<About Studied Examples>

Next, a description will be given of studied examples of the transformer s famed in the semiconductor chip.

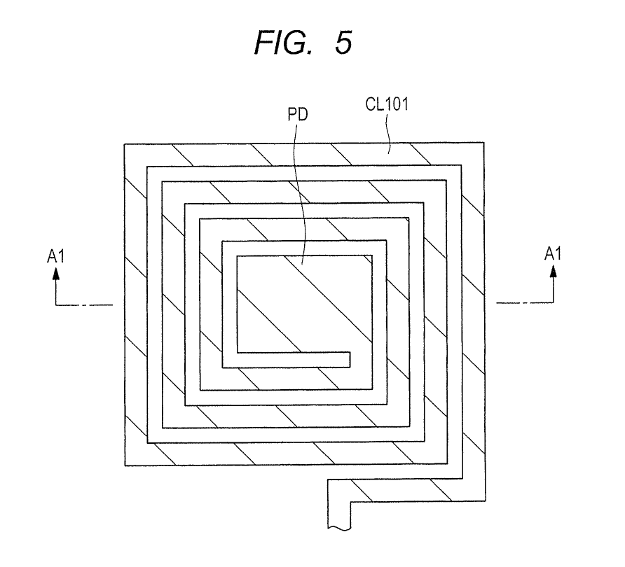

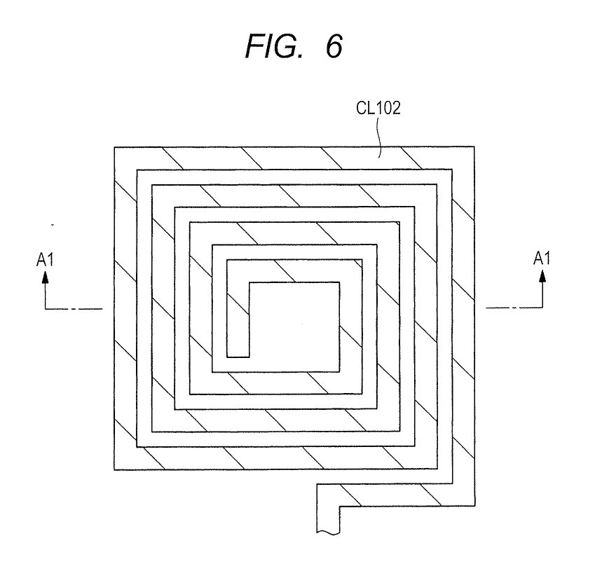

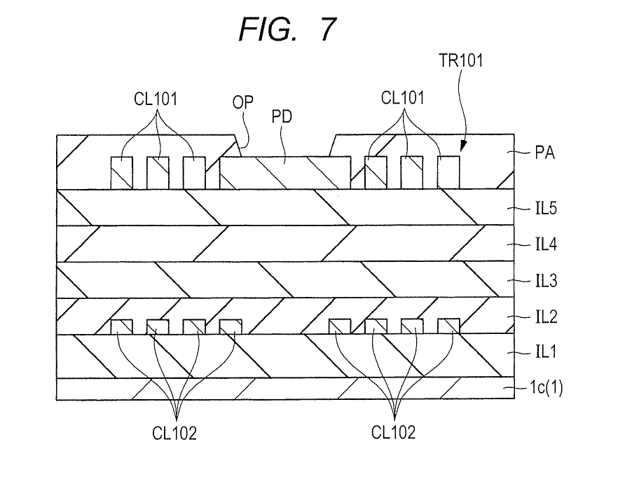

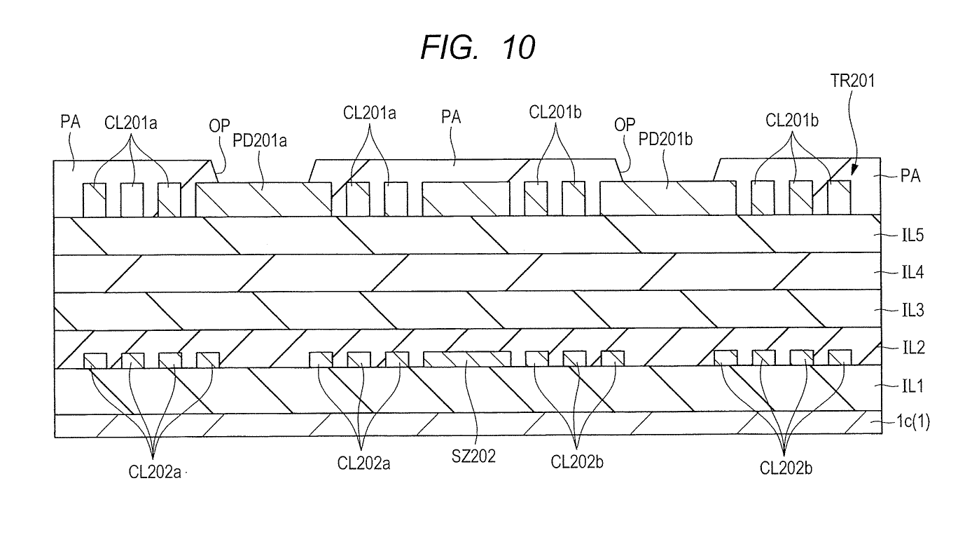

FIGS. 5 and 6 are main-portion plan views of a semiconductor device (semiconductor chip) in the first studied example. FIG. 7 is a main-portion cross-sectional view of the semiconductor device in the first studied example. FIG. 5 shows the pattern of the primary coil of a transformer TR101. FIG. 6 shows the pattern of the secondary coil of the transformer TR101. Note that FIGS. 5 and 6 show the same two-dimensional region in the semiconductor device in the first studied example, but in different layers. FIG. 6 shows the layer located below the layer shown in FIG. 5. The cross section along the line A1-A1 in each of FIGS. 5 and 6 corresponds to FIG. 7. In FIG. 7 and FIG. 10 described later, the illustration of the substrate 1a and the insulating layer 1b of the SOI substrate 1 is omitted.

In the case of the first studied example shown in FIGS. 5 to 7, the primary coil is formed of a spiral coil CL101, while the secondary coil is formed of a spiral coil CL102. The coil CL101 (primary coil) and the coil CL102 (secondary coil) disposed over the coil CL101 are magnetically coupled to each other and a signal is transmitted from a transmission circuit to a reception circuit via the coils CL101 and CL102.

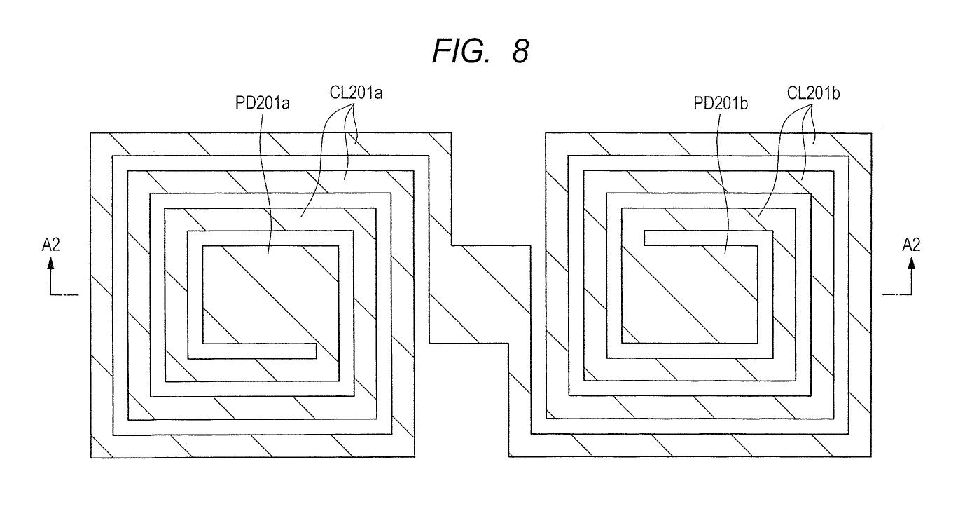

When each of the primary and secondary coils is formed of two coils, i.e., the transformer TR1 is famed of two transformer s and the two transformer s are differentially operated, noise resistance is increased. Accordingly, transformer s which can differentially be operated are studied and shown in FIGS. 8 to 11.

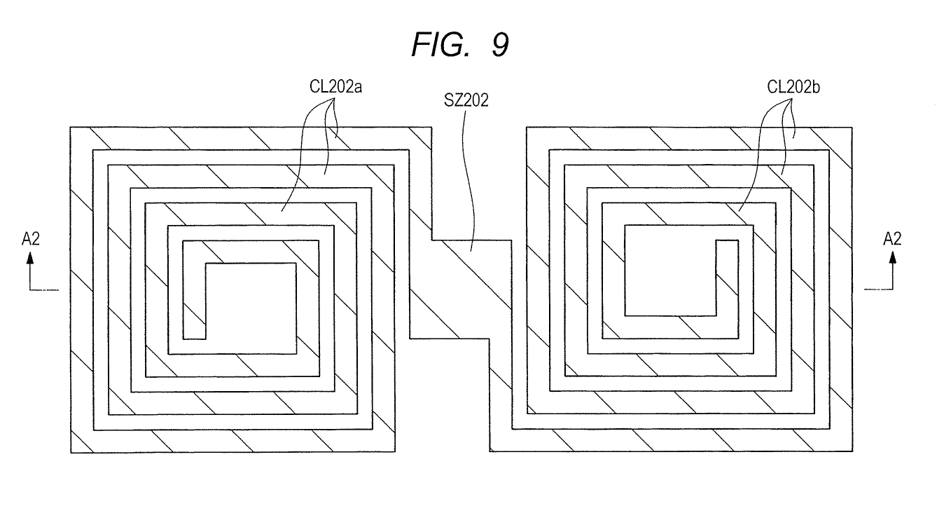

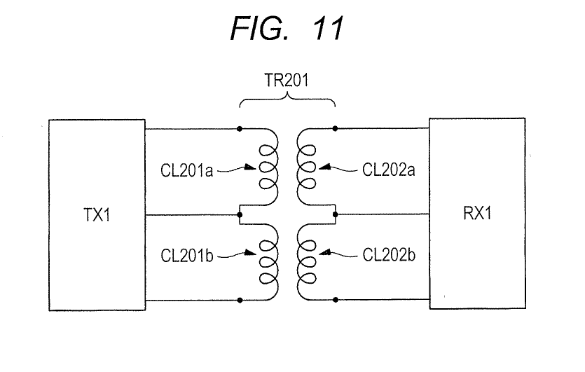

FIGS. 8 and 9 are main-portion plan views of a semiconductor device (semiconductor chip) in the second studied example. FIG. 10 is a main-portion cross-sectional view of the semiconductor device in the second studied example. FIG. 8 shows the pattern of the primary coil of a transformer TR201. FIG. 9 shows the pattern of the secondary coil of the transformer TR201. Note that FIGS. 8 and 9 show the same two-dimensional region in the semiconductor device in the second studied example, but in different layers. FIG. 9 shows the layer located below the layer shown in FIG. 8. The cross section along the line A2-A2 in each of FIGS. 8 and 9 corresponds to FIG. 10. FIG. 11 is a circuit diagram showing a circuit configuration of the transformer TR201.

In the case in the second studied example shown in FIGS. 8 to 11, the primary coil of the transformer TR201 is foisted of two coils CL201a and CL201b coupled in series to each other, while the secondary coil of the transformer TR201 is faulted of two coils CL202a and CL202b coupled in series to each other. Each of the coils CL201a, CL201b, CL202a, and CL202b is formed of a spiral coil. The coils CL202a and CL202b are formed in two-dimensional regions different from each other in plan view. The coil CL201a is disposed over the coil CL202a, while the coil CL201b is disposed over the coil CL202b. The coil CL201a and the coil CL202a disposed over the coil CL201a are magnetically coupled to each other, while the coil CL201b and the coil CL202b disposed over the coil CL201b are magnetically coupled to each other. This allows a signal from a transmission circuit equivalent to the foregoing transmission circuit TX1 to be transmitted by electromagnetic induction to a reception circuit equivalent to the foregoing reception circuit RX1 via the coils CL201a, CL201b, CL202a, and CL202b. Note that, to a coupling terminal SZ202 between the coils CL201a and CL201b, a fixed potential (ground potential or power supply potential) is supplied via the internal wiring (not shown herein). Accordingly, it is possible to detect an induced electromotive force or induced current in the coil CL202a and an induced electromotive force or induced current in the coil CL202b and differentially perform control (an operation).

However, in the case in the second studied example shown in FIGS. 8 to 11, the coil CL202b is formed in the two-dimensional region different from the two-dimensional region where the coil CL202a is formed in plan view. As a result, the size (area) of the two-dimensional region required to form the transformer TR201 therein increases to undesirably increase the size (area) of the semiconductor device. For example, in the case in the second studied example shown in FIGS. 8 to 11, the area of the two-dimensional region required to form the transformer therein is approximately double that in the first studied example shown in FIGS. 5 to 7.

Accordingly, in the case in the first studied example shown in FIGS. 5 to 7, the transformer TR101 cannot differentially be operated so that common-mode noise increases. On the other hand, in the case in the second studied example shown in FIGS. 8 to 11, the transformer TR201 can differentially be operated, but the area of the two-dimensional region required to form the transformer TR201 therein undesirably increases.

<About Configuration of Coils>

Next, a description will be given of a specific configuration of the transformer TR1 (coils included in transformer TR1) formed in the semiconductor chip CP in the present embodiment. Note that the description will be given of the specific configuration of the transformer TR1 (coils included in the transformer TR1), but the description is also applicable to the transformer TR2 (coils included in the transformer TR2).

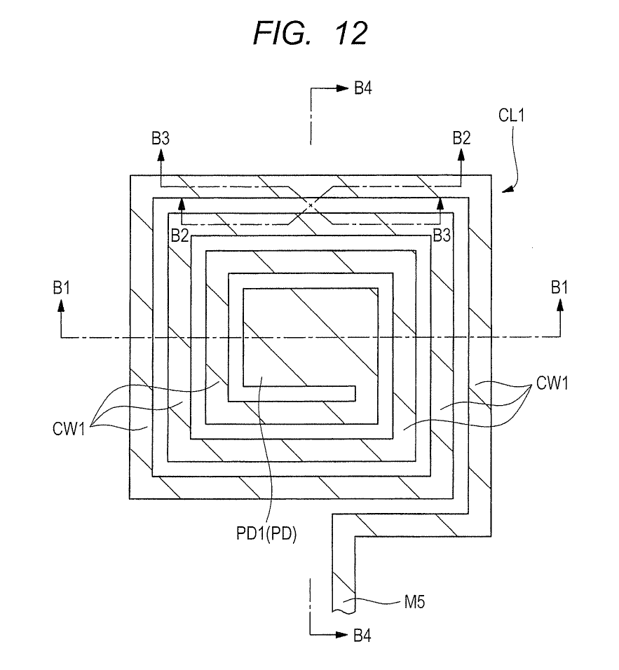

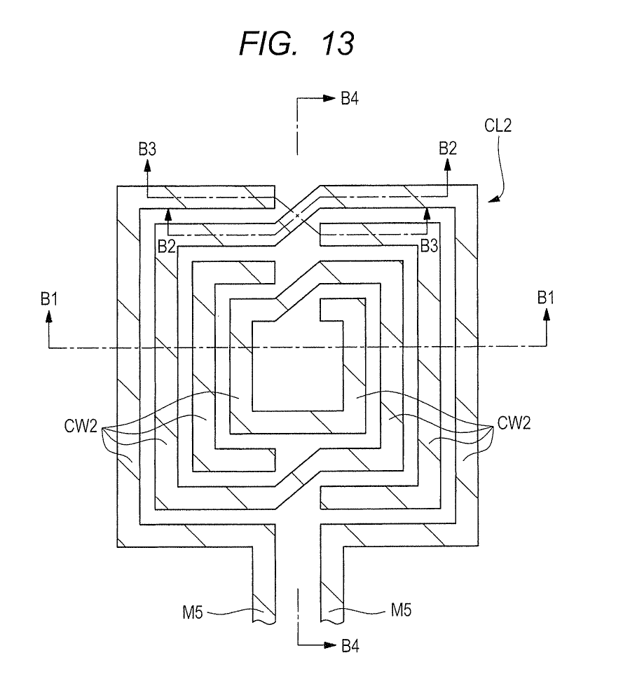

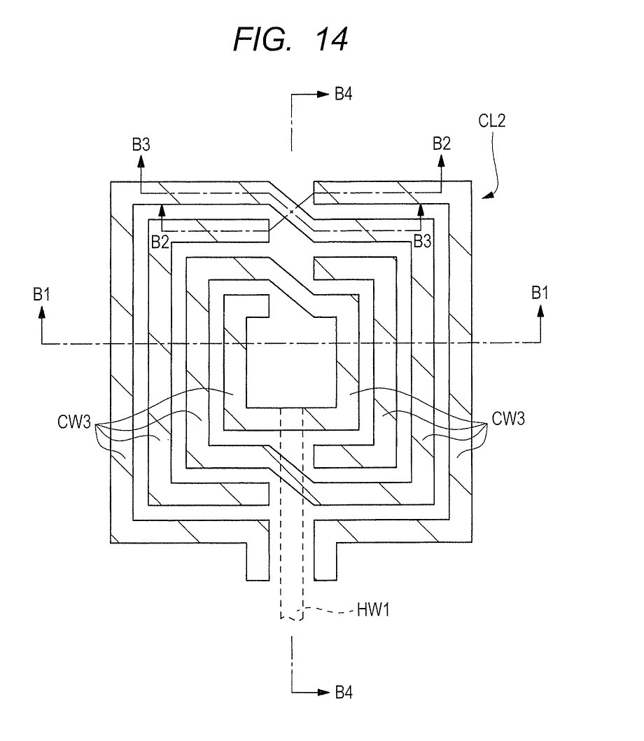

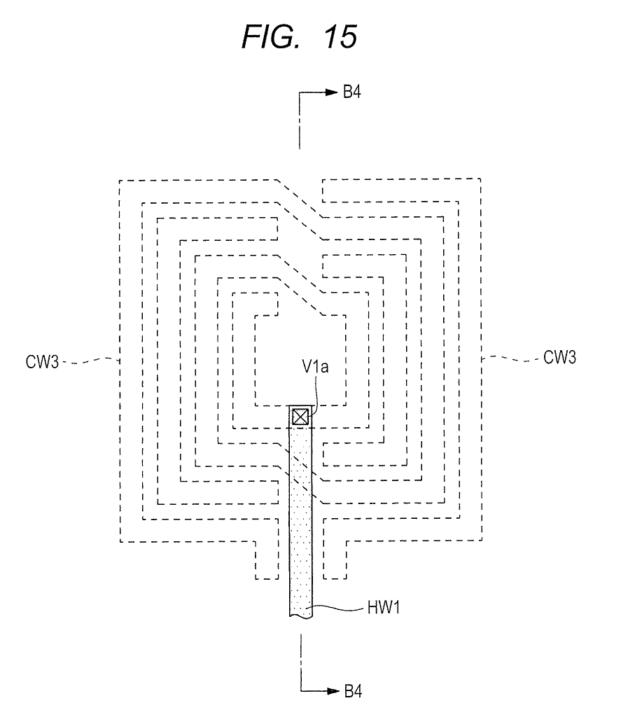

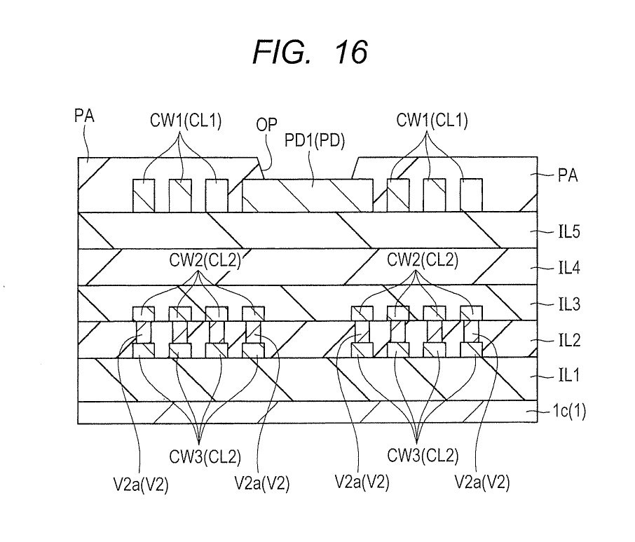

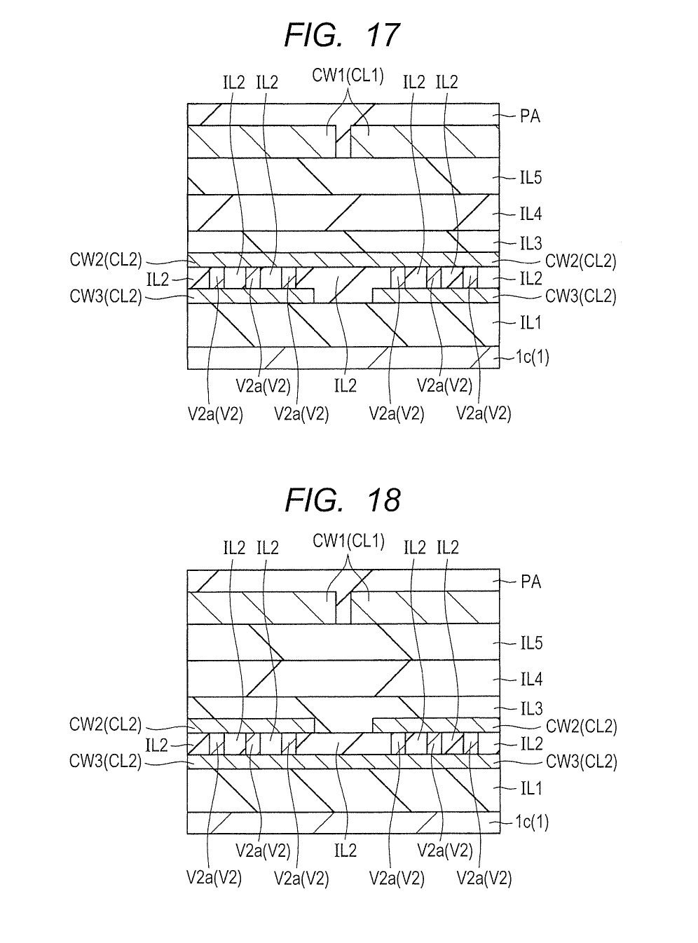

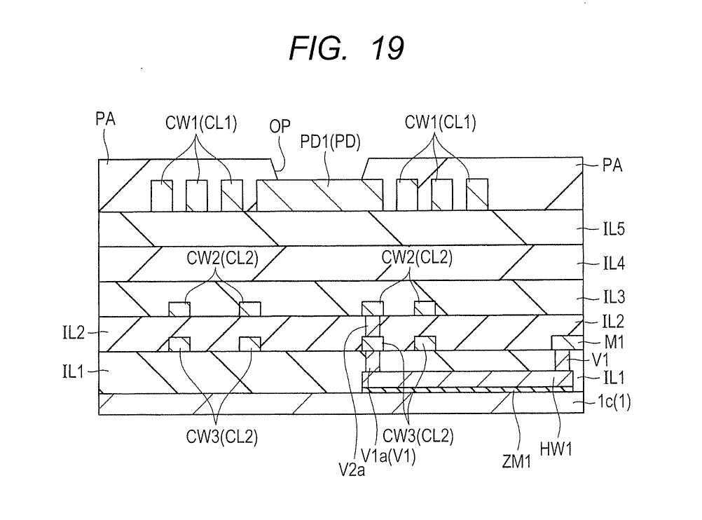

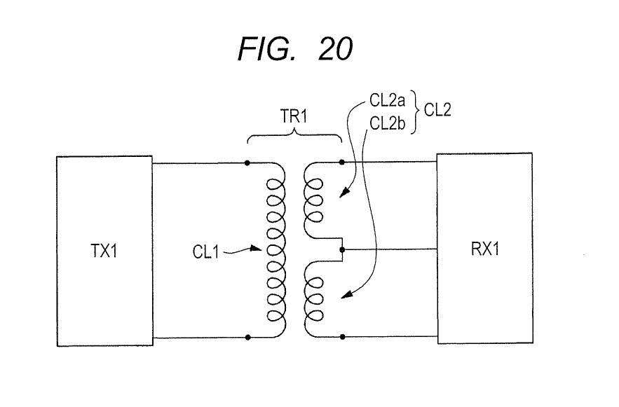

FIGS. 12 to 15 are main-portion plan views of the semiconductor device (semiconductor chip CP) in the present embodiment. FIGS. 16 to 19 are main-portion cross-sectional views of the semiconductor device (semiconductor chip CP) in the present embodiment. FIG. 20 is a circuit diagram showing a circuit configuration of the transformer TR1 formed in the semiconductor chip CP. Note that FIGS. 12, 13, 14, and 15 show the same two-dimensional region (transformer formation region RG2b) in the semiconductor chip CP, but in different layers. FIG. 13 shows the layer located below the layer shown in FIG. 12. FIG. 14 shows the layer located below the layer shown in FIG. 13. FIG. 15 shows the layer located below the layer shown in FIG. 14. The cross section along the line B1-B1 shown in each of FIGS. 12 to 14 corresponds to FIG. 16. The cross section along the line B2-B2 shown in each of FIGS. 12 to 14 corresponds to FIG. 17. The cross section along the line B3-B3 shown in each of FIGS. 12 to 14 corresponds to FIG. 18. The cross section along the line B4-B4 shown in each of FIGS. 12 to 15 corresponds to FIG. 19. The cross section of the transformer formation region RG2b in FIG. 3 described above corresponds to the cross section shown in FIG. 16, i.e., the cross section along the line B1-B1. Note that, in FIGS. 16 to 19, the illustration of the substrate la and the insulating layer 1b of the SOI substrate 1 is omitted.

Specifically, FIG. 12 shows the pattern in the same layer as that of the wires M5 in the transformer formation region RG2b and shows the pattern of the primary coil (coil CL1) of the transformer TR1. FIG. 13 shows the pattern in the same layer as that of the wires M2 in the transformer formation region RG2b. FIG. 14 shows the pattern in the same layer as that of the wires M1 in the transformer formation region RG2b. Each of FIGS. 13 and 14 shows the pattern of the secondary coil (coil CL2) of the transformer TR1. FIG. 15 shows the pattern of a lead-out wire HW1. For easier understanding, in FIG. 14, the position where the lead-out wire HW1 is formed is shown by the dotted line. Also, in FIG. 15, the positions where the coil wires CW3 are foiled are shown by the dotted lines and the lead-out wire HW1 is shown by dot hatching. The lead-out wire HW1 is formed in the layer below the coil wires CW3.

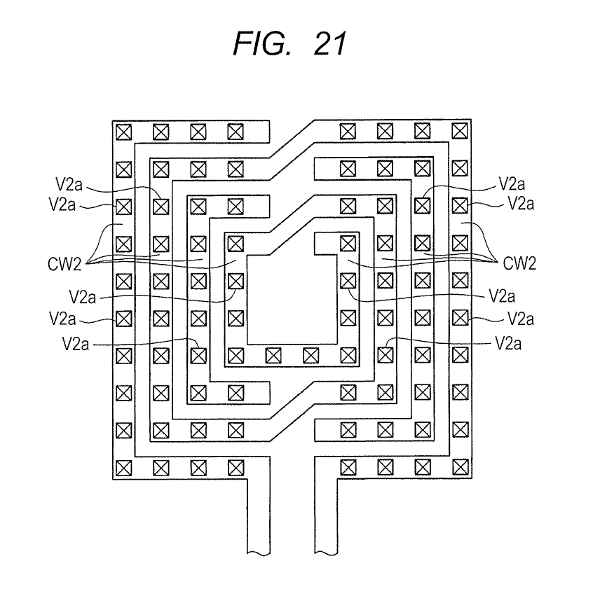

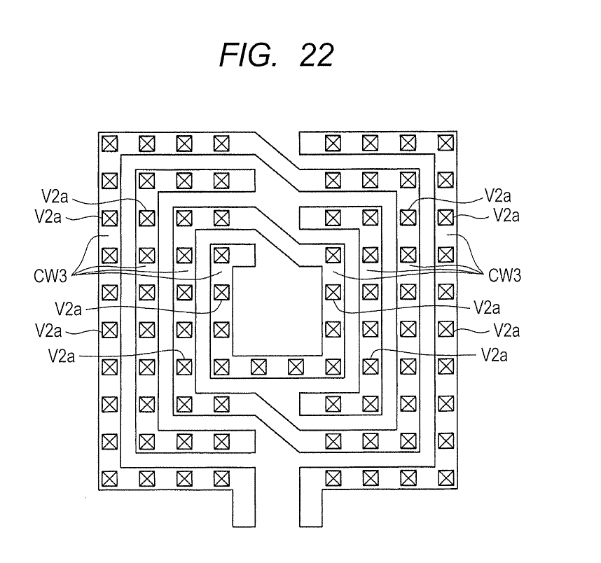

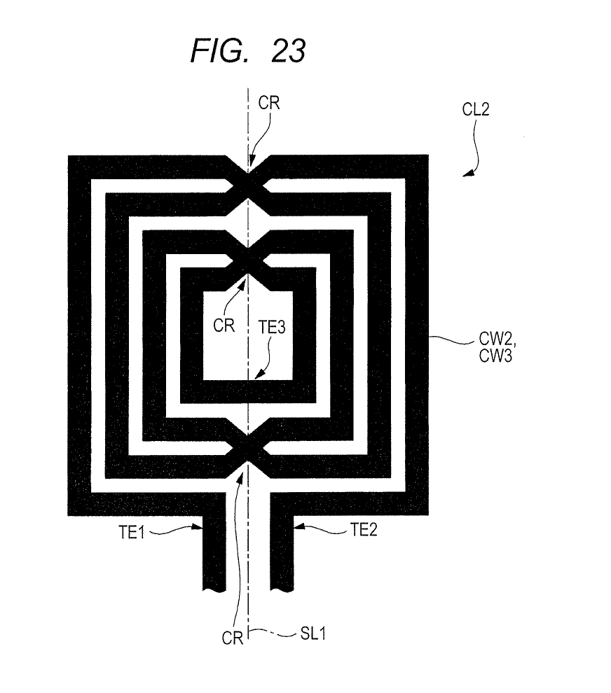

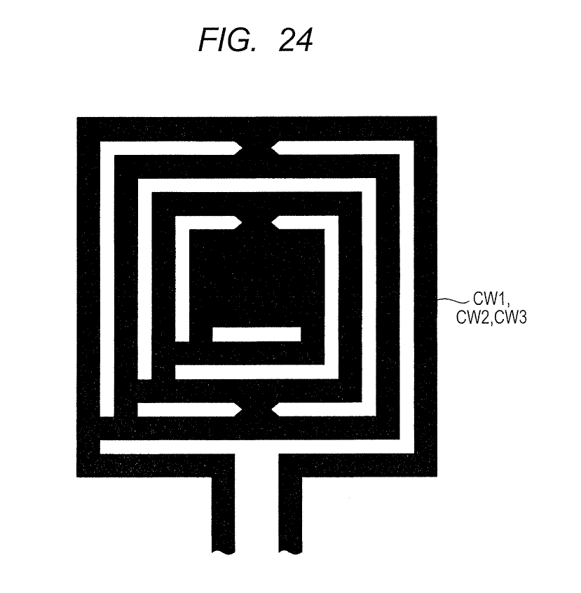

FIGS. 21 to 24 are main-portion plan views of the semiconductor chip CP, which are illustrative views for easier understanding of the coils included in the transformer TR1. FIG. 21 shows the positions of vias V2a in addition to the coil wires CW2 shown in FIG. 13. FIG. 22 shows the positions of the vias V2a in addition to the coil wires CW3 shown in FIG. 14. FIG. 23 corresponds to a plan view obtained by laying the coil wires CW3 shown in FIG. 14 over the coil wires CW2 shown in FIG. 13. FIG. 24 corresponds to a plan view obtained by laying the coil wires CW2 shown in FIG. 13 and the coil wires CW3 shown in FIG. 14 over a coil wire CW1 and a coil pad PD1 which are shown in FIG. 12.

As described above, in the semiconductor chip CP, the primary and secondary coils for the transformer TR1 are formed. Of the primary and secondary coils, the primary coil is formed on the upper side and the secondary coil is formed on the lower side. That is, the primary coil is disposed over the secondary coil and the secondary coil is disposed under the primary coil. The coil (inductor) CL1 is the primary coil for the transformer TR1 and corresponds to the foregoing coil CL11. The coil (inductor) CL2 is the secondary coil for the transformer TR1 and corresponds to the foregoing coil CL12.

First, a description will be given of the primary coil (coil CL1) for the transformer TR1.

As also shown in FIGS. 12 and 16, the primary coil of the transformer TR1 is formed of the one spiral coil CL1. That is, the coil CL1 is formed of the wire (coil wire CW1) winding in a spiral shape (coil shape or loop shape). The coil CL1 forms the primary coil of the transformer TR1. The coil CL1 is faulted of one wiring layer, which is the fifth wiring layer herein. That is, the coil CL1 is formed in the same layer as that of the wires M5 and the pads PD in the same step of forming the wires M5 and the pads PD.

Inside the spiral of the coil CL1, the pad PD is disposed. To the pad PD, one end of the coil CL1 is coupled. It is assumed herein that the pad PD disposed inside the coil CL1 and coupled to the one end of the coil CL1 is denoted by a reference numeral PD1 and referred to as the pad PD1.

That is, the coil wire CW1 having the one end coupled to the pad PD1 is wound around the pad PD1 a plurality of times into a spiral shape (coil shape or loop shape) to form the coil CL1. The coil wire CW1 is formed in the same layer as that of the wires M5 and the pads PD (including the pad PD1) in the same step of forming the wires M5 and the pad PD. In the case of, e.g., forming the wires M5 and the pads PD by patterning the conductive film formed over the interlayer insulating film IL5, not only the wires M5 and the pads PD, but also the coil wire CW1 and the pad PD1 can also be formed when the conductive film is patterned.

The coil CL1 does not have portions (crossing portions) which cross each other in plan view. Accordingly, the coil CL1 can be formed of one (which is the fifth wiring layer herein) of the plurality of wiring layers included in the wiring structure (multilayer wiring structure) formed over the SOI substrate 1.

In the present embodiment, the coil CL1 is formed only of the single-layer coil wire CW1. The wires in the layer above the coil wire CW1 and the wires in the layer below the coil wire CW1 are not included in the coil CL1. Note that the coil wire CW1 has a spiral (helical) continuous pattern not having the crossing portions.

Note that, in the case in FIG. 12, the coil CW1 having the one end coupled to the pad PD1 is wound around the pad PD1 in a right-hand direction (clockwise direction) to form the coil CL1. However, there may also be a case where, in another form, the coil wire CW1 having the one end coupled to the pad PD1 is wound around the pad PD1 in a left-hand direction (counterclockwise direction) to form the coil CL1.

In plan view, the coil wire CW1 forming the coil CL1 does not have portions which cross each other. As a result, every time the coil wire CW1 having the one end coupled to the pad PD1 is wound around the pad PD1 in the right-hand direction (clockwise direction), the coil wire CW1 is gradually displaced farther away from the pad PD1. Accordingly, in plan view, the pattern of the coil CL1 (pattern of the coil wire CW1 forming the coil CL1) is not symmetric (line-symmetric) with respect to a line (line overlapping the line B4-B4) extending through the substantial center of the coil CL1, but is asymmetric. Thus, the coil CL1 is the asymmetric coil. Note that, since the pad PD1 is disposed inside the coil CL1, the substantial center of the coil CL1 substantially corresponds to the substantial center of the pad PD1.

Thus, the coil CL1 (coil wire Cl)W is a spiral pattern and has the one end portion located inside the, spiral and connected to the pad PD1 and the other end portion located outside the spiral and connected to the wire M5.

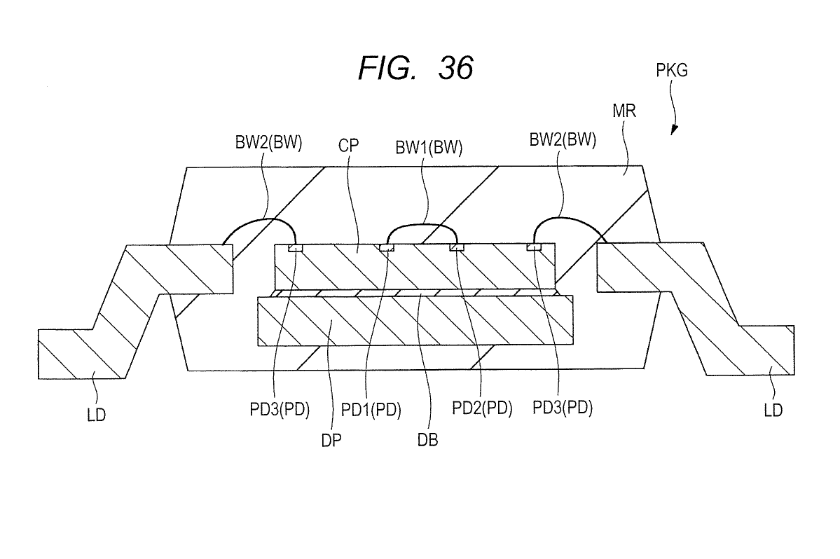

The one end (end portion inside the spiral) of the coil CL1 (coil wire CW1) is coupled to the pad PD1 and specifically connected integrally to the pad PD1. To the pad PD1, one end of the wire BW1 described later is coupled and the other end of the wire BW1 is coupled to another pad PD (corresponding to a pad PD2 described later) of the semiconductor chip CP. Note that the wire BW1 is shown in FIGS. 36 to 38 described later. The pad PD (PD2) coupled to the other end of the wire BW1 is electrically coupled to the transmission circuit TX1 in the semiconductor chip CP via the internal wiring of the semiconductor chip CP. Accordingly, one end of the coil CL1 (coil wire CW1) is electrically coupled to the transmission circuit TX1 formed in the semiconductor chip CP via the pad PD1, the wire BW1, the pad PD2, and the internal wiring of the semiconductor chip CP.

The other end (end portion outside the spiral) of the coil CL1 (coil wire CW1) is coupled to the wire 5 and specifically connected integrally to the wire M5. The wire M5 coupled to the other end of the coil CL1 (coil wire CW1) is electrically coupled to the transmission circuit TX1 in the semiconductor chip CP2 via the wires (M4 to M1) in the layers located therebelow. Accordingly, the other end of the coil CL1 (coil wire CW1) is electrically coupled to the transmission circuit TX1 formed in the semiconductor chip CP via the internal wiring (including the wire M5 coupled to the other end of the coil CL1) of the semiconductor chip CP.

Thus, the coil CL1 is electrically coupled to the transmission circuit TX1 in the semiconductor chip CP via the internal wiring of the semiconductor chip CP and the wire BW1.

Next, a description will be given of the secondary coil (coil CL2) for the transformer TR1.

As shown in FIGS. 13, 14, and 16 to 18, the coil CL2 faulting the secondary coil of the transformer TR1 is formed of two wiring layers, which are the first and second wiring layers herein. The coil CL2 is formed of the coil wires CW2 formed of the second wiring layer, the coil wires CW3 formed of the first wiring layer, and the via portions V2 electrically coupling the coil wires CW2 and CW3 to each other. The coil wires CW3 are formed in the same layer as that of the wires M1 in the same step of forming the wires M1. The coil wires CW2 are formed in the same layer as that of the wires M2 in the same step of forming the wires M2.

In the case of, e.g., forming the wires M1 by patterning the conductive film fouled over the interlayer insulating film IL1, when the conductive film is patterned, not only the wires Ml, but also the coil wires CW3 can be faulted. Also, in the case of forming the wires M2 by patterning the conductive film formed over the interlayer insulating film IL2, when the conductive film is patterned, not only the wires M2, but also the coil wires CW2 can be formed.

On the other hand, in the case of, e.g., forming the wires M1 using a damascene method, the coil wires CW3 can also be formed in the same step of forming the wires M1 using a damascene method. In this case, the wires M1 and the coil wires CW3 are each formed of the conductive film (e.g., conductive film containing copper as a main component) embedded in the trenches of the interlayer insulating film. Also, in the case of forming the wires M2 using a damascene method, the coil wires CW2 can also be formed in the same step of forming the wires M2 using a damascene method. In this case, the wires M2 and the coil wires CW2 are each formed of the conductive film (e.g., conductive film containing copper as a main component) embedded in the trenches of the interlayer insulating film.

It is assumed herein that the via portions V2 electrically coupling the coil wires CW2 and CW3 to each other is denoted by a reference numeral V2a and referred to as the via portions V2a. Preferably, the plurality of via portions V2a are provided to electrically couple the coil wires CW2 and CW3 to each other. The via portions V2a are formed in the same step of forming the via portions V2 (i.e., via portions V2 coupling the wires M1 and M2 to each other) foamed in the peripheral circuit formation regions RG1a and RG2a.

The via portions V2a are disposed at the positions where the coil wires CW2 and CW3 overlap each other in plan view. That is, the via portions V2a are formed between the coil wires CW2 and CW3, i.e., in the interlayer insulating film IL2 to electrically couple the coil wires CW2 and CW3 to each other. The upper surfaces of the via portions V2 are in contact with the coil wires CW2 and electrically coupled to the coil wires CW2. The lower surfaces of the via portions V2 are in contact with the coil wires CW3 and electrically coupled to the coil wires CW3. In the case of integrally forming the via portions V2 with the wires M2, the via portions V2a are formed integrally with the coil wires CW2.

As shown in FIG. 13, the coil wires CW2 do not cross each other in plan view. As also shown in FIG. 14, the coil wires CW3 do not cross each other in plan view but, as can be seen from FIGS. 13, 14, and 23, the coil wires CW2 and CW3 have respective portions crossing each other. It is assumed that the respective portions of the coil wires CW2 and CW3 which cross each other are denoted by a reference numeral CR and referred to as the crossing portions CR. The crossing portions CR are shown in FIG. 23. In the case in FIG. 23, there are the three crossing portions CR.

Since the coil CL2 is formed below the coil CL1, the coil CL1 has one end coupled to the pad PD1, but the coil CL2 is not coupled to the pad PD. Consequently, the coil CL2 is electrically coupled to the reception circuit RX1 in the semiconductor chip CP via the internal wiring of the semiconductor chip CP without extending through the pad PD.

In plan view, the pattern of the coil CL2 (two-dimensional pattern obtained by laying the coils CW3 over the coils CW2 and corresponding to the pattern shown in FIG. 23) is substantially symmetric (line-symmetric) with respect to a line (line of symmetry, axis of symmetry, or center line) SL1 extending through the substantial center of the coil CL2. Accordingly, the coil CL2 is a symmetric coil. The coil CL2 is also a differential coil (differential spiral inductor), while the foregoing coil CL1 is a non-differential coil (non-differential spiral inductor). Note that the line SL1 corresponds to the foregoing line B4-B4 in plan view.

The following is a specific description of the pattern of the coil CL2. The coil CL2 is formed between a terminal (terminal portion or end portion) TE1 and a terminal (terminal portion or end portion) TE2 (see FIG. 23). The terminals TE1 and TE2 correspond to the both ends of the coil CL2 and are at positions substantially symmetric (line-symmetric) with respect to the line SL1. That is, the line SL1 extends through the substantial middle between the terminals TE1 and TE2. In plan view, the coil CL2 extends from the terminal TE1 and is inwardly (radially inwardly) shifted upon crossing the line SL1 after making each half turn. After making a full innermost turn, the coil CL2 is outwardly (radially outwardly) shifted upon crossing the line SL1 after making each half turn to reach the terminal TE2. The position where the coil CL2 is radially inwardly shifted and the position where the coil CL2 is radially outwardly shifted are on the line SL1 in plan view. The pattern of the portions of the coil CL2 which are radially inwardly shifted and the pattern of the portions of the coil CL2 which are radially outwardly shifted cross each other in plan view to form the crossing portions CR of the coil CL2. The crossing portions CR of the coil CL2 (i.e., the portions of the coil CL2 which cross each other in plan view) are on the line SL1.

As can be seen from FIGS. 13, 14, and 23, in the crossing portions CR of the coil CL2, neither the coil wires CW2 nor the coil wires CW3 cross each other, but the coil wires CW2 and the coil wires CW3 cross each other in plan view. In each of the crossing portions CR of the coil CL2, a position where the coil wire CW2 is broken and is not famed is provided and a position where the coil wire CW3 is broken and is not formed is provided. Thus, the coil wires CW2 and the coil wires CW3 are caused to cross each other in plan view. As a result, in the crossing portions of the coil CL2, the coils CW2 and the coils CW3 cross each other in plan view, but neither the coil wires CW2 nor the coil wires CW3 cross each other.

If the coil wires CW2 cross each other or the coil wires CW3 cross each other in plan view, the coil CL2 is short-circuited halfway and therefore cannot successfully be formed. However, in the present embodiment, neither the coils CL2 nor the coil wires CW3 cross each other, but the coils CW2 and the coils CW3 are caused to cross each other in plan view. This prevents the coil CL2 from being short-circuited halfway and allows the coil wires CW2 and CW3 and the plurality of via portions V2a electrically coupling the coil wires CW2 and CW3 to each other to appropriately form the coil CL2.

In the coil CL2, except in the crossing portions CR, the coils CW2 and CW3 are formed at the same two-dimensional positions in the same pattern. That is, the coil CL2 includes the coil wires CW2 and CW3 and the via portions V2a electrically coupling the coil wires CW2 and CW3 to each other, except in the crossing portions CR. The coil wires CW2 and CW3 overlap each other (are coincident with each other) in plan view, except in the crossing portions CR of the coil CL2.

Between the coils CL1 and CL2, i.e., between the coil wire CW1 foaming the coil CL1 and the coil wires CW2 forming the coil CL2, one or more insulating layers are interposed. Specifically, the interlayer insulating films IL3, IL4, and IL5 are interposed. Accordingly, the coils CL1 and CL2 are not connected via a conductor, but are in an electrically isolated state. However, the coils CL1 and CL2 are magnetically coupled to each other. It is possible to ensure the breakdown voltage between the coil CL1 and the coil CL2 (coils CL2a and CL2b) using the interlayer insulating films IL3, IL4, and IL5 interposed between the coil wires CW1 and CW2.

Also, in plan view, a terminal (terminal portion) TE3 is provided at the position at substantially the center of the coil CL2 and on the line SL1. To the terminal TE3, the lead-out wire HW1 is electrically coupled via the plug V1 (V1a) (see FIGS. 15, 19, and 23). It is assumed herein that the plug V1 located between the coil wire CW3 and the lead-out wire HW1 to electrically couple the coil wire CW3 to the lead-out wire HW1 is denoted by a reference numeral V1a and referred to as the plug (via portion) Via. The plug V1a is provided at the position where the coil wire CW3 and the lead-out wire HW1 overlap each other in plan view. The terminal TE3 corresponds to the portion (part) of the coil wire CW3 which is coupled to the plug V1a. Note that the plugs V1 and V1a can also be regarded as via portions.

The lead-out wire HW1 is the wire (conductor pattern) in the layer below the coil wires CW3. The lead-out wire HW1 is formed herein of the conductor pattern (e.g., doped polysilicon pattern) in the same layer as that of the gate electrode GE. The gate electrode GE is formed by patterning a conductive film such as a doped polysilicon film and, when the conductive film is patterned, the lead-out wire HW1 can also be formed simultaneously. In this case, the lead-out wire HW1 is formed over the semiconductor layer 1c of the SOI substrate 1 via an insulating film ZM1. The insulating film ZM1 is in the same layer as that of the gate insulating film of the foregoing MISFET 3 and formed in the same step of forming the gate insulating film of the foregoing MISFET 3.

Consequently, the coil CL2 has a configuration in which the coil (inductor) CL2a formed between the terminals TE1 and TE3 and the coil (inductor) CL2b formed between the terminals TE3 and TE2 are coupled in series to each other. That is, the coil wires CW2 and CW3 (and the via portions V2a) extending from the terminal TE1 to the terminal TE3 form the coil CL2a and the coil wires CW2 and CW3 (and the via portions V2a) extending from the terminal TE3 to the terminal TE2 form the coil CL2b. The two series-coupled coils CL2a and CL2b correspond to the coil CL2. The portions of the coils CL2a and CL2b which are coupled to each other correspond to the terminal TE3. The coils CL2a and CL2b are formed in the same layer.

Since the coil CL2 is halved and used as the series-coupled coils CL2a and CL2b, the coils CL2a and CL2b are disposed in the same two-dimensional region. That is, the coil CL2 (symmetric secondary coil) disposed under the coil CL1 (symmetric primary coil) is halved and used as the series-coupled coils CL2a and CL2b. This allows the secondary coil to be differentially operated without increasing the two-dimensional size required to dispose the coils.

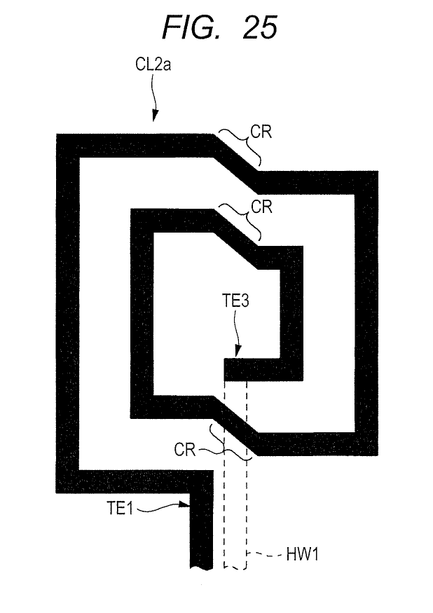

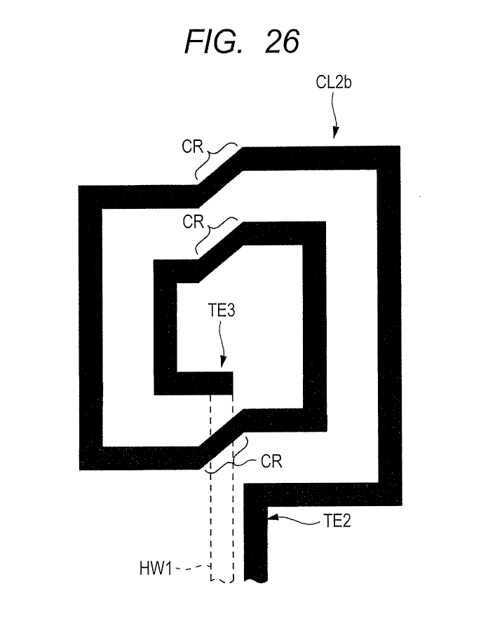

FIG. 25 is a plan view showing the pattern of the coil CL2a. FIG. 26 is a plan view showing the pattern of the coil CL2b. Note that, for easier understanding, in each of FIGS. 25 and 26, the position where the lead-out wire HW1 is formed is shown by the dotted line. By laying the pattern of the coil CL2b shown in FIG. 26 over the pattern of the coil CL2a shown in FIG. 25, the pattern of the coil CL2 shown in FIG. 23 is obtained.

As can also be seen from FIGS. 23, 25, and 26, the coil CL2a which winds in the right-hand direction (clockwise direction) from the outside of the spiral (terminal TE1) toward the inside of the spiral (terminal TE3) and the coil CL2b which winds in the right-hand direction (clockwise direction) from the inside of the spiral (terminal TE3) toward the outside of the spiral (terminal TE2) are disposed in the same two-dimensional region and coupled in series to each other to form the differential coil CL2. In other words, the coil CL2b which winds in the left-hand direction (counterclockwise direction) from the outside of the spiral (end TE2) toward the inside of the spiral (terminal TE3) and the coil CL2a which winds in the left-hand direction (counterclockwise direction) from the inside of the spiral (terminal TE3) toward the outside of the spiral (terminal TE1) are disposed in the same two-dimensional region and coupled in series to each other to form the differential coil CL2. Each of the coils CL2a and CL2b has the pattern in which the coil CL2a or CL2b winds in a spiral shape (coil shape or loop shape) in plan view. However, the coils CL2a and CL2b wind in opposite directions.

Specifically, the coil CL2 has a structure in which the inner end portion of the coil CL2a (inner end portion of the spiral) and the inner end portion of the coil CL2b (inner end portion of the spiral) are connected. To the connected portions (coupled portions) of the coils CL2a and CL2b, the lead-out wire HW1 is electrically coupled via the plug V1a. From another perspective, by coupling the lead-out wire HW1 to substantially the center of the coil CL2 via the plug Via, the coil CL2 is divided into the two coils CL2a and CL2b at the coupled portion (the portion thereof coupled to the plug V1a) thereof. Accordingly, the portion coupled to the plug V1a corresponds to the coupled portions (connected portions) of the coils CL2a and CL2b. That is, the portion of the coil CL2 which is coupled to the lead-out wire HW1, more specifically the portion of the coil CL2 which is coupled to the plug V1a corresponds to the inner end portion of the coil CL2a and corresponds also to the inner end portion of the coil CL2b.

Note that the coils CL2a and CL2b disposed in the layer below the coil CL1 are formed in the same layer. The coils CL2a and CL2b are disposed in the same two-dimensional region. Specifically, both of the coils CL2a and CL2b are disposed so as to overlap the coil CL1 in plan view. As a result, the coils CL2a and CL2b overlap each other in the crossing portions CR in plan view and do not overlap each other in the portions other than the crossing portions CR.

The coils CL2a and CL2b wind in opposite directions. It is assumed herein that, when the direction in which a coil or a coil wire winds (direction of the spiral thereof) is mentioned, the direction indicates the direction of winding from the outside of the spiral toward the inside of the spiral when the coil or the coil wire is viewed from above (from the top surface of the semiconductor chip CP. The coil or coil wire which seems to wind clockwise from the outside of the spiral toward the inside of the spiral when viewed from above is referred to as the “right-handed” coil or coil wire. The coil or coil wire which seems to wind counterclockwise from the outside of the spiral toward the inside of the spiral when viewed from above is referred to as the “left-handed” coil or coil wire. In the case in FIGS. 25 and 26, the coil CL2a is right-handed and the coil CL2b is left-handed. In the case in FIG. 12, the coil CL1 is left-handed, but can also be right-handed.

Since the coil CL2 is symmetric, the coils CL2a and CL2b have two-dimensional shapes (two-dimensional patterns) symmetric (line-symmetric) to each other. From another perspective, in plan view, the coils CL2a and CL2b have a mirror-image relationship therebetween. Accordingly, the coils CL2a and CL2b wind in opposite directions, but the number of windings (the number of go-arounds or the number of turns) of the coil CL2a is the same as the number of windings (the number of go-arounds or the number of turns) of the coil CL2b. In the case illustrated herein as an example, the number of windings of the coil CL2a and the number of windings of the coil CL2b are 2. However, the number of windings of the coil CL2a and the number of winding of the coil CL2b are not limited thereto and can variously be changed. However, the number of windings of the coil CL2a and the number of winding of the coil CL2b are preferably plural numbers.

Preferably, the self-inductance of the coil CL2a is substantially the same as the self-inductance of the coil CL2b. Also, the mutual inductance between the magnetically coupled coils CL1 and CL2a is preferably substantially the same as the mutual inductance between the magnetically coupled coils CL1 and CL2b. Also, in plan view, the size (area) of the two-dimensional region where the coil CL1 is formed is preferably substantially the same as the size (area) of the two-dimensional region where the coil CL2 is formed.

In the case where the two series-coupled coils CL2a and CL2b winding in different directions are disposed in the same two-dimensional region, the coils CL2a and CL2b have the respective crossing portions CR in plan view. That is, the crossing portions CR described above correspond to the respective portions of the coils CL2a and CL2b which cross each other in plan view. Each of the coils CL2a and CL2b is formed of two wiring layers, i.e., formed of the coil wires CW2 and CW3. Each of the crossing portions CR has a structure in either of first and second cases described next.

In the first case, in each of the crossing portions CR, the coil wire CW2 is formed but the coil wire CW3 is not foamed for the coil CL2a, while the coil wire CW3 is formed but the coil wire CW2 is not formed for the coil CL2b. In the first case, in each of the crossing portions CR, the coil wire CW3 of the coil CL2b can pass through the portion of the coil CL2a where the coil wire CW3 is not formed (the broken portion of the coil wire CW3). Also, in each of the crossing portions CR, the coil wire CW2 of the coil CL2a can pass through the portion of the coil CL2b where the coil wire CW2 is not formed (the broken portion of the coil wire CW2). This can prevent a short circuit between the coils CL2a and CL2b in each of the crossing portions CR.

In the second case, in each of the crossing portions CR, the coil wire CW3 is formed but the coil wire CW2 is not formed for the coil CL2a, while the coil wire CW2 is formed but the coil wire CW3 is not formed for the coil CL2b. In the second case, in each of the crossing portions CR, the coil wire CW2 of the coil CL2b can pass through the portion of the coil CL2a in which the coil wire CW2 is not formed (the broken portion of the coil wire CW2). Also, in each of the crossing portions CR, the coil wire CW3 of the coil CL2a can pass through the portion of the coil CL2b in which the coil wire CW3 is not formed (the broken portion of the coil wire CW3). This can prevent a short circuit between the coils CL2a and CL2b in each of the crossing portions CR.

Thus, in the present embodiment, the coils CL2a and CL2b are coupled in series to each other and are also disposed in the same two-dimensional region. As a result, the coils CL2a and CL2b have the crossing portions CR which cross each other. However, in each of the crossing portions CR, only one of the coil wires CW2 and CW3 is formed for the coil CL2a, while only the other of the coil wires CW2 and CW3 is foamed for the coil CL2b. As a result, a short circuit between the coils CL2a and CL2b does not occur in any of the crossing portions CR.

The terminal TE1 as the one end of the coil CL2a (outer end portion of the spiral) is electrically coupled to the wire M2. Specifically, the end portion of the coil wire CW2 forming the coil CL2a which corresponds to the terminal TE1 is integrally connected to the wire M2. The wire M2 coupled to one end of the coil CL2a is electrically coupled to the reception circuit RX1 in the semiconductor chip CP via the internal wiring of the semiconductor chip CP.

The terminal TE2 as the one end of the coil CL2b (outer end portion of the spiral) is electrically coupled to the wire M2. Specifically, the end portion of the coil wire CW2 forming the coil CL2b which corresponds to the to/urinal TE2 is integrally connected to the wire M2. The wire M2 coupled to one end of the coil CL2b is electrically coupled to the reception circuit RX1 in the semiconductor chip CP via the internal wiring of the semiconductor chip CP.

In another fault, it may also be possible that the terminal TE1 as the one end of the coil CL2a is electrically coupled not to the wire M2, but to the wire M1 or, alternatively, the terminal TE1 is electrically coupled to both of the wires M1 and M2. Likewise, it may also be possible that the terminal TE2 as the one end of the coil CL2b is electrically coupled not to the wire M2, but to the wire M1 or, alternatively, the terminal TE2 is electrically coupled to both of the wires M1 and M2.

The terminal TE3 (the portion of the coil wire CW3 which faults the terminal TE3) as the respective coupled portions of the coils CL2a and CL2b is electrically coupled to the lead-out wire HW1 via the plug V1a. The lead-out wire HW1 is electrically coupled to the wire M1 via another of the plugs V1 (see FIG. 19). As a result, the terminal TE3 as the coupled portions of the coils CL2a and CL2b is electrically coupled to the lead-out wire HW1 via the plug V1a, further electrically coupled to the wire M1 via the plug V1 (plug V1 coupling the lead-out wire HW1 and the wire M1 to each other), and further electrically coupled to the reception circuit RX1 in the semiconductor chip CP via the internal wiring (internal wiring of the semiconductor chip CP) including the wire M1. To the terminal TE3 as the coupled portions of the coils L2a and CL2b, a fixed potential (such as ground potential or power supply potential) is supplied via the internal wiring of the semiconductor chip CP, the lead-out wire HW1, and the plug V1a.

Thus, the coils CL2a and CL2b are electrically coupled to the reception circuit RX1 in the semiconductor chip CP via the internal wiring of the semiconductor chip CP and the lead-out wire HW1. Note that, preferably, the wires M3 and M4 are not disposed between the coil wire CW1 forming the coil CL1 and the coil wire CW2 forming the coil CL2.

When the secondary coil is formed of the two coils (CL2a and CL2b), i.e., the transformer TR1 is formed of the two transformers and the two transformer s are differentially operated, noise resistance increases.

Accordingly, the present embodiment uses a configuration in which the secondary coil (equivalent to the foregoing coil CL11) of the transformer TR1 is formed of the series-coupled coils CL2a and CL2b and the primary coil (equivalent to the foregoing coil CL12) of the transformer TR1 is formed of the common coil CL1. In the region located under the coil CL1 and overlapping the coil CL1 in plan view, the series-coupled coils CL2a and CL2b are disposed. In this case, each of the coils CL2a and CL2b is magnetically coupled (inductively coupled) to the coil CL1. Specifically, the coils CL2a and CL1 are magnetically coupled (inductively coupled) to each other, while the coils CL2b and CL1 are magnetically coupled (inductively coupled) to each other. In other words, the coils CL2a and CL1 are not connected via a conductor, but are magnetically coupled to each other, while the coils CL2b and CL1 are not connected via a conductor, but are magnetically coupled to each other. On the other hand, the coils CL2a and CL2b are connected via a conductor and electrically coupled in series to each other.

The coil CL1 is electrically coupled to the transmission circuit TX1. The series-coupled coils CL2a and CL2b are electrically coupled to the reception circuit RX1. Accordingly, when a transmission signal is sent from the reception circuit TX1 to the coil CL1 as the primary coil to cause a current to flow in the semiconductor chip CP, an induced electromotive force is generated in each of the coils CL2a and CL2b as the secondary coil in accordance with a change in the current flowing in the coil CL1 so that an induced current flows therein. The induced electromotive force or the induced current generated in each of the coils CL2a and CL2b can be sensed by the reception circuit RX1 in the semiconductor chip via the internal wiring of the semiconductor chip CP. This allows the signal from the transmission circuit TX1 of the semiconductor chip CP to be transmitted by electromagnetic induction to the reception circuit RX1 of the semiconductor chip CP via the coils CL1, CL2a, and CL2b. To the terminal TE3 between the series-coupled coils CL2a and CL2b, the fixed potential (such as ground potential or power supply potential) is supplied. Therefore, it is possible to detect the induced electromotive force or induced current in the coil CL2a and the induced electromotive force or induced current in the coil CL2b and differentially control (operate) the coils CL2a and CL2b.

The foregoing transformer TR2 of the semiconductor chip CP can also have the same configuration as that of the transformer TR1 of the semiconductor chip CP. Accordingly, it is possible to form the foregoing coil CL1 as the foregoing coil CL21 and form the foregoing coil CL2 (i.e., series-coupled coils CL2a and CL2b) as the foregoing coil CL22. However, a repeated description thereof is omitted herein.

In the case illustrated herein, the number of the wiring layers formed over the SOI substrate 1 is 5 (the total of five layers respectively include the wires M1, M2, M3, M4, and M5), the number of the wiring layers is not limited to 5 and can variously be changed. However, the number of the wiring layers is preferably not less than 3. Thus, it is possible to form the coil CL2 of two of three or more wiring layers and form the coil CL1 of one of the three or more wiring layers.

<About Main Characteristic Features and Effects of Semiconductor Device (Semiconductor Chip)>

In the present embodiment, the semiconductor device (semiconductor chip) has the SOI substrate 1 as a semiconductor substrate, the wiring structure formed over the SOI substrate 1 and including the plurality of wiring layers, and the coil CL1 (first coil), the coil CL2a (second coil), and the coil CL2b (third coil) which are formed above the SOI substrate 1. In the region located under the coil CL1 and overlapping the coil CL1 in plan view, the coils CL2a and CL2b are disposed. The coils CL2a and CL2b are formed in the same layer and electrically coupled in series to each other. Each of the coils CL2a and CL2b is not coupled to the coil CL1 via a conductor, but is magnetically coupled to the coil CL1.

One of the main characteristic features of the present embodiment is that the coils CL2a and CL2b formed in the same layer and electrically coupled in series to each other are disposed in the region located under the coil CL1 and overlapping the coil CL1 in plan view. Each of the coils CL2a and CL2b is magnetically coupled to the coil CL1.

In the case in the first studied example shown in FIGS. 5 to 7 described above, the one coil CL102 is disposed under the CL101 and the coils CL101 and CL102 are magnetically coupled to each other. However, in this case, a differential operation cannot be performed so that resistance to noise such as common-mode noise decreases. This leads to the degradation of the performance of the semiconductor device.

On the other hand, in the second studied example shown in FIGS. 8 to 11 described above, under the two coils CL201a and CL201b coupled in series to each other and disposed at different positions in plan view, the two coils CL202a and CL202b coupled in series to each other and disposed at different positions in plan view are disposed. The coils CL201a and CL201b are magnetically coupled to each other, while the coils CL202a and CL202b are magnetically coupled to each other. The coils CL201a and CL201b are disposed at the different positions in plan view. The coil CL202a is disposed in the region located under the coil CL201a and overlapping the coil CL201a in plan view. The coil CL202b is disposed in the region located under the coil CL201b and overlapping the coil CL201b in plan view.

In the case in the second studied example shown in FIGS. 8 to 11 described above, each of the primary and secondary coils is formed of the two series-coupled coils so that the differential operation is possible. Accordingly, it is possible to enhance resistance to noise such as common-mode noise. However, in the case in the second studied example shown in FIGS. 8 to 11 described above, the coils CL202a and CL202b are formed in the two different two-dimensional regions. The coil CL202a is formed under the coil CL201a, while the coil CL202b is fatted under the coil CL201b. This undesirably increases the size (area) of the two-dimensional region required to foam the transformer to increase the two-dimensional size (area) of the semiconductor device.

By contrast, in the present embodiment, below the one coil CL1, the two coils CL2a and CL2b formed in the same layer and electrically coupled in series to each other are disposed in the region overlapping the coil CL1 in plan view. Since the two coils CL2a and CL2b are coupled in series to each other, a differential operation is possible and resistance to noise such as common-mode noise can be enhanced. This allows an improvement in the performance of the semiconductor device. In addition, in the present embodiment, the two coils CL2a and CL2b coupled in series to each other are disposed in the region located under the coil CL1 and overlapping the coil CL1 in plan view. Accordingly, it is possible to reduce the size (area) of the two-dimensional region required to foam the transformer. For example, the size (area) of the two-dimensional region required to form the transformer TR1 in the present embodiment can be reduced to be substantially equal to the size (area) of the two-dimensional region required to form the transformer TR101 in the foregoing first studied example and can also be reduced to about half the size (area) of the two-dimensional region required to form the transformer TR201 in the foregoing second studied example. Thus, it is possible to reduce the two-dimensional size (area) of the semiconductor device and reduce the size (area) of the semiconductor device.

Therefore, in the present embodiment, it is possible to simultaneously achieve an improvement in the performance of the semiconductor device resulting from an improvement in noise resistance and a reduction in the size of the semiconductor device resulting from a reduction in the two-dimensional region required to form the transformer.

Also, in the present embodiment, a further reduction can be achieved in the total area of the transformer s than in the case in the foregoing second studied example, as described above. This also allows a reduction in common-mode noise. That is, the common-mode noise depends also on the capacitance between the primary and secondary coils and tends to increase when the capacitance between the primary and secondary coils increases. In the present embodiment, a further reduction can be achieved in the total area of the transformers than in the case in the foregoing second studied example. As a result, the effect of reducing the capacitance between the primary and secondary coils and reducing the common-mode noise can also be obtained. This allows an improvement in the performance of the semiconductor device.

The gain (signal propagation property) of the transformer depends also on the resistance of the primary coil. When the resistance of the primary coil decreases, the gain tends to increase. The gain mentioned herein is a value obtained by dividing the output voltage of the secondary coil by the input voltage of the primary coil. To improve the performance of the semiconductor device, the gain is preferably larger. In the case in the second studied example described above, the primary coil has the configuration in which the two coils CL201a and CL201b are coupled in series to each other so that the resistance of the primary coil increases. By contrast, in the present embodiment, as the primary coil, the one coil CL1 is used. Accordingly, the resistance of the primary coil can be reduced to be lower in the present embodiment than in the foregoing second studied example. Consequently, in the present embodiment, the gain (signal propagation property) of the transformer can further be improved than in the foregoing second studied example. This allows an improvement in the performance of the semiconductor device.

In the foregoing second studied example, as the primary coil of the transformer, the two spiral coils (CL201a and CL201b) are provided and used in a series-coupled configuration. However, in the present embodiment, as the primary coil of the transformer, only one spiral coil (CL1) is used and, under the one spiral coil (CL1), the two series-coupled coils CL2a and CL2b are disposed as the secondary coil of the transformer. This allows an improvement in the performance of the semiconductor device, as described above. This also allows a reduction in the size of the semiconductor device.

A further description will be given of the other characteristic features of the present embodiment.

In the present embodiment, over the SOI substrate 1, the wiring structure (multilayer wiring structure) including the plurality of wiring layers is formed and the coil CL1 is formed of one of the plurality of wiring layers included in the wiring structure. Since the coil CL1 does not have portions (crossing portions) which cross each other in plan view, the coil CL1 can be formed of one of the wiring layers. By forming the coil CL1 of one of the wiring layers, it is possible to increase the distance (space) between the coil CL1 and each of the coils CL2a and CL2b and increase the thickness of the insulating layer interposed between the coil CL1 and each of the coils CL2a and CL2b. This can increase the breakdown voltage between the coil CL1 and each of the coils CL2a and CL2b. A detailed description will be given thereof with reference to a third studied example.

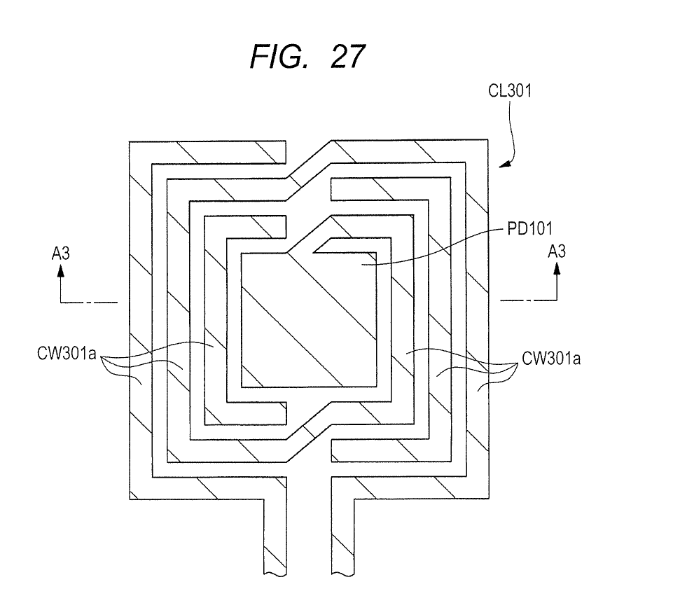

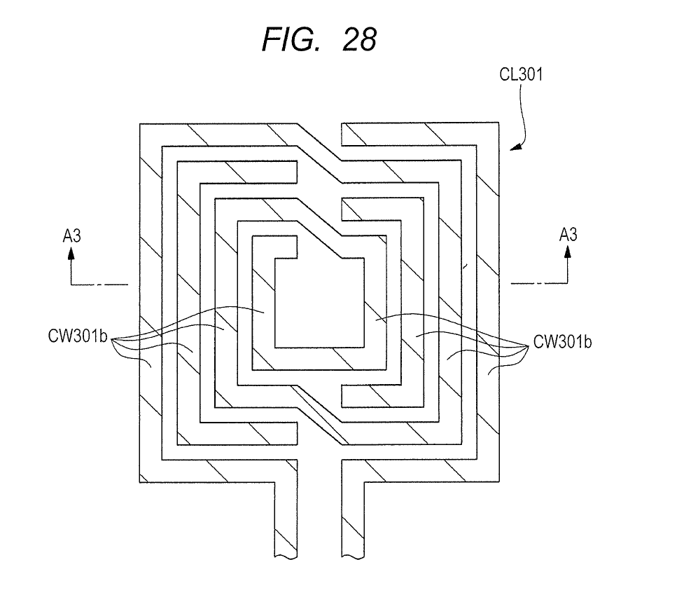

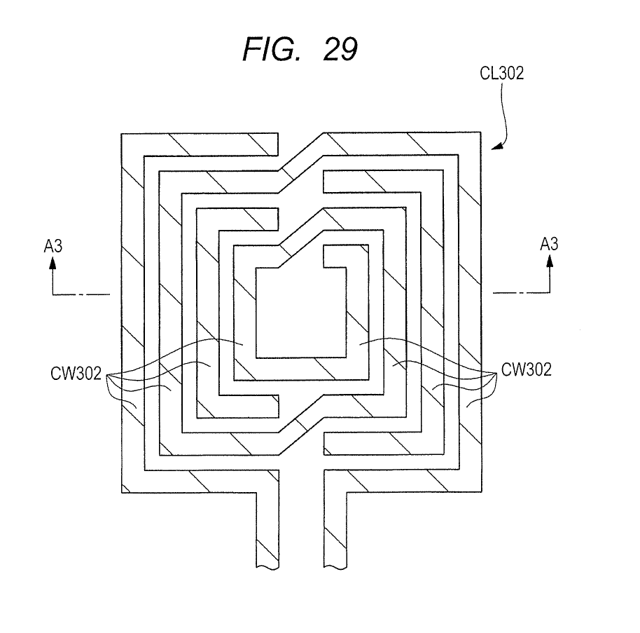

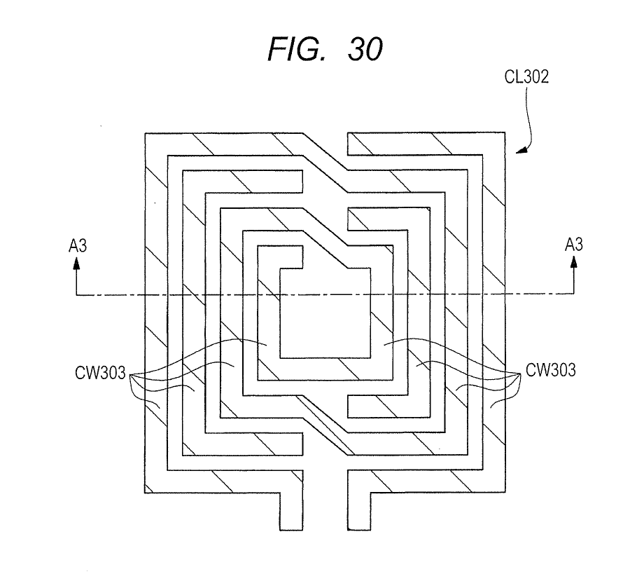

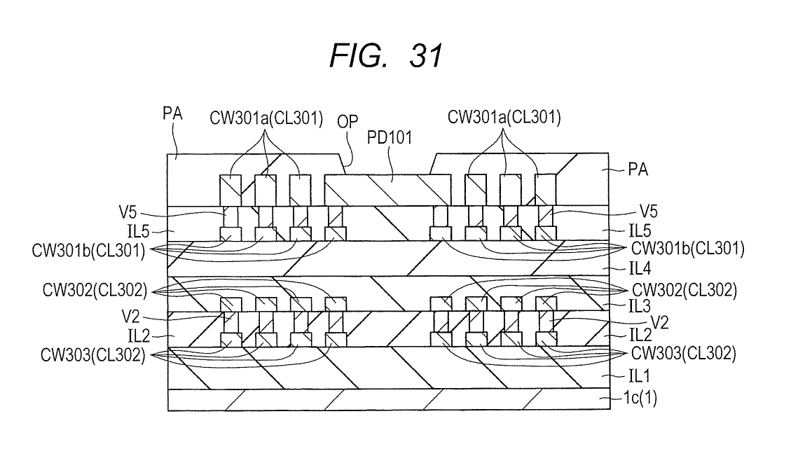

FIGS. 27 to 30 are main-portion plan views of a semiconductor device (semiconductor chip) in the third studied example. FIG. 31 is a main-portion cross-sectional view of the semiconductor device (semiconductor chip) in the third studied example. FIGS. 27, 28, 29, and 30 show the same two-dimensional region in the semiconductor device, but in different layers. FIG. 28 shows the layer located below the layer shown in FIG. 27. FIG. 29 shows the layer located below the layer shown in FIG. 28. FIG. 30 shows the layer located below the layer shown in FIG. 29. The cross section along the line A3-A3 shown in FIGS. 27 to 30 corresponds to FIG. 31. Note that, in FIG. 31, the illustration of the substrate 1a and the insulating layer 1b in the SOI substrate 1 is omitted.

Specifically, FIG. 27 shows a pattern in the transformer formation region which is in the same layer as that of the wires M5. FIG. 28 shows a pattern in the transformer formation region which is in the same layer as that of the wires M4. Each of FIGS. 27 and 28 shows the pattern of a primary coil (coil CL301) of a transformer TR301. FIG. 29 shows a pattern in the transformer formation region which is in the same layer as that of the wires M2. FIG. 30 shows a pattern in the transformer formation region which is in the same layer as that of the wires M1. Each of FIGS. 29 and 30 shows the pattern of a secondary coil (coil CL302) of the transformer TR301.

In the case in the third studied example, the secondary coil CL302 of the transformer TR301 is formed of coil wires CW302 formed of the second wiring layer, coil wires CW303 formed of the first wiring layer, and the via portions V2 electrically coupling the coil wires CW302 and CW303 to each other. It is to be noted herein that the configuration of the coil CL302 is substantially the same as the configuration of the foregoing coil CL2, the coil wires CW302 have the same pattern as that of the foregoing coil wires CW2, and the coil wires CW303 have the same pattern as that of the foregoing coil wires CW3. Accordingly, a description of the coil CL302 is omitted herein.

In the case in the third studied example, the primary coil CL301 of the transformer TR301 is formed of the two wiring layers. Specifically, the primary coil CL301 is formed of coil wires CW301a formed of the fifth wiring layer, coil wires CW301b formed of the fourth wiring layer, and the via portion V5 electrically coupling the coil wires CW301a and CW301b to each other. In plan view, inside the coil CL301, a pad PD101 coupled to one end of the coil CL301 is disposed.

In the case in the third studied example, the pattern of the coil wires CW301a of the primary coil is basically the same as that of the coil wires CW302 of the secondary coil, and the pattern of the coil wires CW301b of the primary coil is basically the same as that of the coil wires CW303 of the secondary coil. Accordingly, the primary coil CL301 has the configuration of a differential coil, similarly to the secondary coil CL302.

In the case in the third studied example, not only the secondary coil CL302, but also the primary coil CL301 has crossing portions in plan view. As a result, it is necessary to form the secondary coil CL302 of two wiring layers (which are the first and second wiring layers herein) and also form the primary coil CL301 of other two (which are the fifth and fourth wiring layers herein) of the wiring layers. This is because, in the case where a coil has crossing portions in plan view, when the coil is formed only of one wiring layer, the coil is short-circuited halfway and the coil cannot be formed.

Accordingly, in the case in the third studied example, it is necessary to form each of the primary and secondary coils CL301 and CL302 of two wiring layers. As a result, the distance (space in the thickness direction) between the primary and secondary coils CL301 and CL302 is reduced and the thickness of the insulating layers interposed between the coils CL301 and CL302 is reduced. This decreases the breakdown voltage between the coils CL301 and CL302.

By contrast, in the present embodiment, the coil CL1 does not have portions (crossing portions) crossing each other in plan view and can therefore be formed of one wiring layer. Accordingly, the distance (space in the thickness direction) between the primary and secondary coils can be increased to be larger in the present embodiment in which the coil CL1 is formed of the one wiring layer than in the case in the third studied example in which the coil CL301 is formed of the two wiring layers. This can increase the thickness (total thickness) of the insulating layers interposed between the primary and secondary coil and thus further increase the breakdown voltage between the primary and secondary coils.

For example, in the case in the third studied example, as can be seen from FIG. 31, the breakdown voltage between the primary and secondary coils is ensured using the interlayer insulating films IL3 and IL4 interposed between the primary and secondary coils. However, in the case in the present embodiment, as can be seen from FIG. 16, the breakdown voltage between the primary and secondary coils is ensured using the interlayer insulating films IL3, IL4, and IL5 interposed between the primary and secondary coils. The breakdown voltage between the primary and secondary coils can be increased to be accordingly higher due to the interlayer insulating film IL5 in the present embodiment in FIG. 16 than in the third studied example in FIG. 31.

Also, in the present embodiment, the coil CL1 is formed of the one wiring layer and does not have crossing portions. Consequently, with regard to the coil CL1, a differential operation cannot be performed. However, for an improvement in noise resistance, the secondary coil needs to be differentially operated and the primary coil need not be differentially operated. Accordingly, in the present embodiment, the series-coupled coils CL2a and CL2b are used as the secondary coil to be able to be differentially operated and thus allow an improvement in noise resistance. On the other hand, a differential operation is not used for the primary coil, but noise resistance is not reduced thereby. Accordingly, as the primary coil, the one coil CL1 formed of one wiring layer and not having crossing portions can be used. This allows the above-mentioned effect of increasing the breakdown voltage between the primary coil (CL1) and the secondary coils (CL2a and CL2b) to be obtained.

Also, in the present embodiment, the coil CL1 is preferably formed of the uppermost one (which is the fifth wiring layer herein) of the plurality of wiring layers included in the wiring structure. This can increase the distance (space in the thickness direction) between the coil CL1 and each of the coils CL2a and CL2b and increase the thickness (total thickness) of the insulating layers interposed between the coil CL1 and each of the coils CL2a and CL2b. Consequently, the breakdown voltage between the coil CL1 and each of the coils CL2a and CL2b can be increased. In addition, the uppermost wiring layer (which is the fifth wiring layer herein) is thicker than the wiring layers located therebelow (which are the first to fourth wiring layers herein). Accordingly, by forming the coil CL1 of the uppermost wiring layer, it is possible to increase the thickness of the coil CL1 and thus reduce the resistance of the coil CL1.

As described above, to increase the gain of the transformer, it is effective to reduce the resistance of the primary coil. In the present embodiment, by forming the primary coil (CL1) of the uppermost wiring layer (which is the fifth wiring layer herein), it is possible to increase the thickness of the primary coil (CL1) and reduce the resistance of the primary coil (CL1). This allows the gain (signal propagation property) to be improved.

Also, in the present embodiment, the pad (pad electrode or bonding pad) PD1 coupled to one end of the coil CL1 is preferably disposed inside the coil CL1 (coil wire CW1) in plan view.

In the case where the pad PD1 is not disposed inside the coil CL1 (coil wires CW1) unlike in the present embodiment, the need arises to provide a lead-out wire (which traverses the coil wire CW1 in plan view) for leading out the inner end portion of the coil CL1 (coil wire CW1) in a layer located below the coil CL1 (coil wire CW1). However, when such a lead-out wire is formed, the dielectric breakdown voltage between the lead-out wire and the coil CL2 (coil wires CW2) becomes dominant as the breakdown voltage of the transformer, which may reduce the breakdown voltage of the transformer.

By contrast, in the present embodiment, the pad PD1 is disposed inside the coil CL1 (coil wire CW1). As a result, it is possible to couple the inner end portion of the coil CL1 (coil wire CW1) to the pad PD1 without forming a lead-out wire (lead-out wire for leading out the inner end portion of the coil CL1). It is also possible to electrically couple the inner end portion of the coil CL1 (coil wire CW1) to the transmission circuit TX1 via the coupling member (corresponding to a wire BW1 described later) coupled to the pad PD1. This eliminates the need to form a lead-out wire between the coil CL1 (coil wire CW1) and the coil CL2 (coil wires CW2). As a result, the dielectric breakdown voltage between the coil CL1 (coil wire CW1) and the coil CL2 (coil wires CW2) becomes dominant as the dielectric breakdown of the transformer to allow the breakdown voltage of the transformer to be improved.

Also, in the present embodiment, the wiring structure (multilayer wiring structure) including the plurality of wiring layers is formed over the SOI substrate 1. Each of the coils CL2a and CL2b is formed of the two of the plurality of wiring layers included in the wiring structure. The coils CL2a and CL2b have the crossing portions CR which cross each other in plan view but, since each of the coils CL2a and CL2b is formed of the two wiring layers, the two series-coupled coils CL2a and CL2b can appropriately be formed without being short-circuited halfway.

Specifically, in each of the crossing portions CR of the coils CL2a and CL2b, the coil CL2a is formed only one of the two wiring layers (coil wires CW2 and CW3), while the coil CL2b is formed only of the other of the two wiring layers (coil wires CW2 and CW3). In this manner, the two series-coupled coils CL2a and CL2b can appropriately be formed without being short-circuited halfway.

Thus, in the present embodiment, the primary coil which need not be differentially operated is formed of the one wiring layer so as not to have crossing portions. This increases the distance (space in the thickness direction) between the primary coil (CL1) and each of the secondary coils (CL2a and CL2b) and thus improves the breakdown voltage between the primary coil (CL1) and each of the secondary coils (CL2a and CL2b). On the other hand, the secondary coil which is preferably differentially operated is famed of the two wiring layers so as to have crossing portions (CR) which cross each other in plan view. Thus, the series-coupled two coils CL2a and CL2b are disposed in the same two-dimensional region to be able to be differentially operated, while the two-dimensional region required to form the transformer is reduced. This can achieve both of an improvement in the performance of the semiconductor device and a reduction in the size thereof.

Preferably, the coils CL2a and CL2b are wound in opposite directions and have two-dimensional shapes line-symmetric to each other in plan view. This allows the coils CL2a and CL2b to have substantially equal self-inductances and allows the magnetically-coupled coils CL1 and CL2a and the magnetically-coupled coils CL1 and CL2b to have substantially equal mutual inductances therebetween. As a result, the differential operation can more appropriately be performed.

The common-mode noise depends also on the resistance of the secondary coil. As the resistance of the secondary coil decreases, the common-mode noise tends to decrease. In the present embodiment, by forming the secondary coil (CL2a and CL2b) of the two wiring layers, the effect of reducing the resistance of the secondary coil (CL2a and CL2b) and reducing the common-mode noise can also be obtained. Each of the crossing portions CR of the coils CL2a and CL2b is formed of one of the wiring layers (i.e., one of the coil wires CW2 and CW3), but each of the portions of the coils CL2a and CL2b other than the crossing portions CR is preferably formed of the two wiring layers (i.e., both of the coil wires CW2 and CW3). Thus, it is possible to further reduce the resistance of the secondary coil (CL2a and CL2b) and further reduce the common-mode noise.

Also, in the present embodiment, to the coupled portions (i.e., terminal TE3) of the coils CL2a and CL2b, the lead-out wire HW1 in the layer located below the two wiring layers forming the coils CL2a and CL2b is electrically coupled.

In the case where the lead-out wire HW1 is formed in a layer located above the two wiring layers forming the coils CL2a and CL2b, specifically in the case where the lead-out wire HW1 is formed in an layer located above the coil wires CW2, the dielectric breakdown voltage between the lead-out wire HW1 and the coil CL1 (coil wire CW1) becomes dominant as the breakdown voltage of the transformer. By contrast, in the present embodiment, the lead-out wire HW1 is famed in the layer below the two wiring layers forming each of the coils CL2a and CL2b. As a result, the dielectric breakdown voltage between the coil CL1 (coil wire CW1) and the coil CL2 (coil wires CW2) becomes dominant as the breakdown voltage of the transformer. This can improve the breakdown voltage of the transformer.

In addition, the supply of the fixed potential from the lead-out wire HW1 to the coupled portions (i.e., TE3) of the coils CL2a and CL2b allows the differential operation to be appropriately performed.

In the present embodiment, since the coil CL2 (coils CL2a and CL2b) is formed of the lowermost wiring layer (first wiring layer) and the wiring layer (second wiring layer) located immediately thereabove, the lead-out wire HW1 is formed in the layer below the first wiring layer. In the case where the coil CL2 is famed of the second and third wiring layers in another faun, i.e., where the coil wires CW3 are formed in the same layer as that of the wires M2 and the coil wires CW2 are formed in the same layer as that of the wires M3, the lead-out wire HW1 can also be famed of the first wiring layer (wires M1). In this case, the foregoing plug V1a serves as a via portion formed in the same layer as that of the foregoing via portions V2 in the same step of forming the via portions V2. In the case where the coil CL2 is formed of the third and fourth wiring layers in still another form, the lead-out wire HW1 can also be formed of the second wiring layer (wires M2). In this case, the foregoing plug V1a serves as a via portion formed in the same layer as that of the foregoing via portions V3 in the same step of forming the via portions V3. However, in the case where the coil CL2 is formed of the first and second wiring layers as in the present embodiment, it is possible to increase the distance (space in the thickness direction) between the coils CL1 and CL2 (coils CL2a and CL2b) and increase the thickness (total thickness) of the insulating layers interposed between the coils CL1 and CL2. This can further increase the breakdown voltage between the coils CL1 and CL2.

In the case where the coil CL2 (coils CL2a and CL2b) is formed of the lowermost wiring layer (first wiring layer) and the wiring layer (second wiring layer) located immediately thereabove, the lead-out wire HW1 can be formed of a conductive pattern (conductor pattern) in the same layer as that of the gate electrodes GE of the MISFETs 3. That is, the lead-out wire HW1 can be formed in the same layer as that of the gate electrodes GE of the MISFETs 3 in the same step of forming the gate electrodes GE. This can reduce the number of the steps in the manufacturing process of the semiconductor device.

The respective coupled portions (i.e., terminal TE3) of the coils CL2a and CL2b are electrically coupled to the lead-out wire HW1 via the via portion (which is the plug V1a herein). This allows the fixed potential to be supplied from the lead-out wire HW1 to the coupled portions (i.e., terminal TE3) of the coils CL2a and CL2b via the via portion (which is the plug V1a herein).

Referring to FIGS. 14, 15, and 32 to 35, a further description will now be given of the position of the plug V1a (via portion) electrically coupling the respective coupled portions (i.e., terminal TE3) of the coils CL2a and CL2b to the lead-out wire HW1.

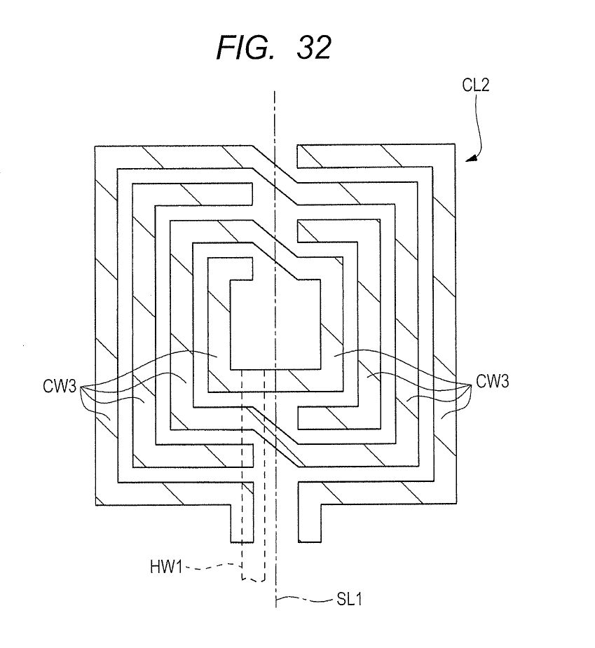

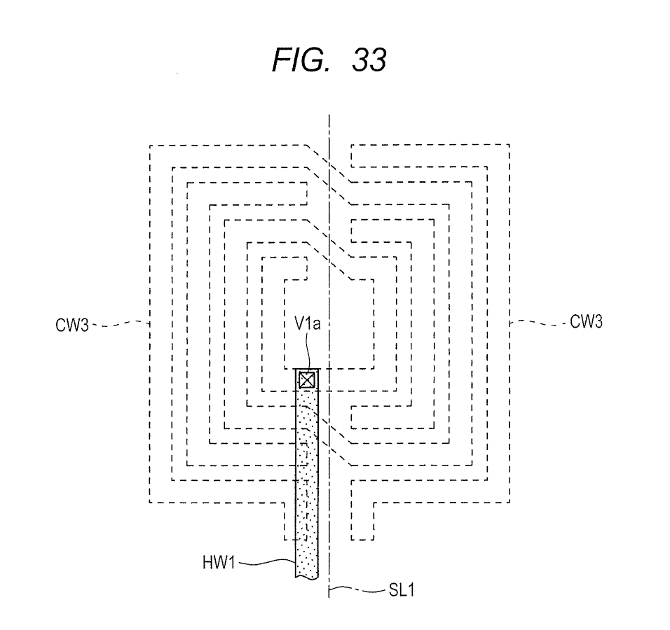

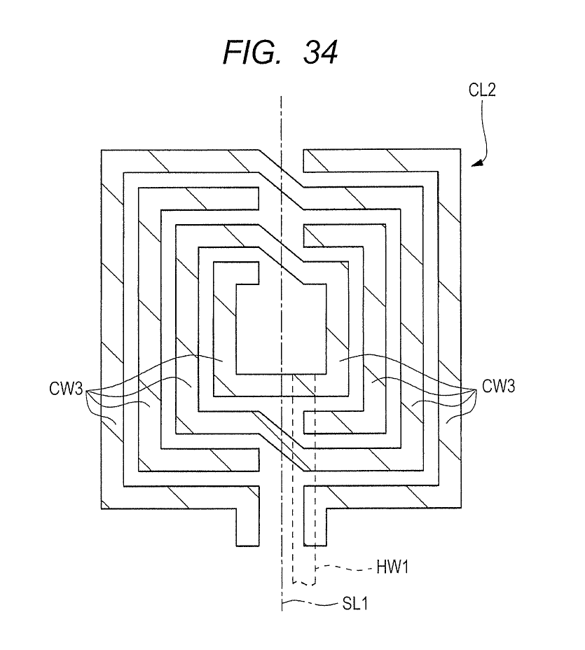

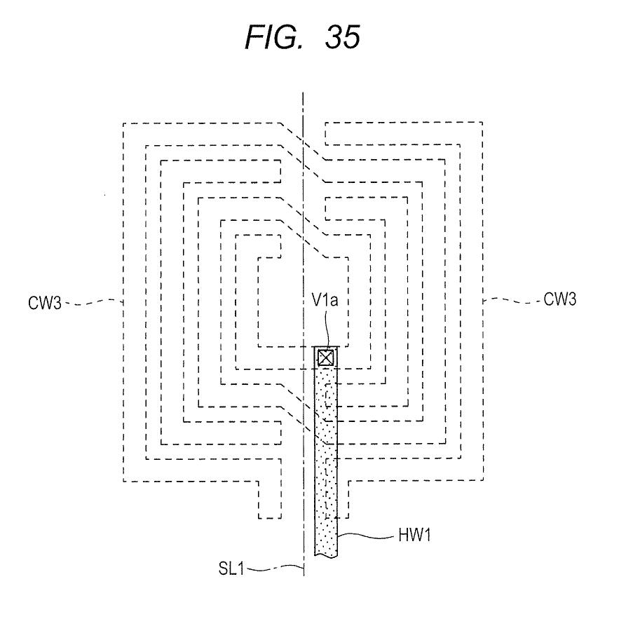

FIGS. 32 and 33 are main-portion plan views of a semiconductor device (semiconductor chip CP) in a first modification. FIGS. 34 and 35 are main-portion plan views of a semiconductor device (semiconductor chip CP) in a second modification. FIGS. 32 and 34 correspond to FIG. 14 described above. FIGS. 33 and 35 correspond to FIG. 15 described above. Accordingly, in FIGS. 32 and 34, the coil wires CW3 are shown by the solid lines and hatched with oblique lines and the position where the lead-out wire HW1 is formed is shown by the dotted line, in the same manner as in FIG. 14 described above. Also, in FIGS. 33 and 35, the lead-out wire HW1 is shown by the solid line and hatched with dots and the positions where the coil wires CW3 are formed are shown by the dotted lines, in the same manner as in FIG. 15 described above. The position of the plug V1a is shown in FIGS. 15, 33, and 35.

The semiconductor device in the first modification shown in FIGS. 32 and 33 is different from the semiconductor device shown in FIGS. 12 to 26 described above in the respective positions of the lead-out wire HW1 and the plug V1a. The semiconductor device in the second modification shown in FIGS. 34 and 35 is different from the semiconductor device shown in FIGS. 12 to 26 described above in the respective positions of the lead-out wire HW1 and the plug V1a. The semiconductor device in the first modification shown in FIGS. 32 and 33 and the semiconductor device in the second modification shown in FIGS. 34 and 35 have otherwise substantially the same configuration as that of the semiconductor device shown in FIGS. 12 to 26 described above.

In the case in FIGS. 14 and 15 described above, in plan view, the plug V1a is disposed on the center line (corresponding to the foregoing line SL1) extending through the center of the coil pattern (i.e., coil CL2) including the series-coupled coils CL2a and CL2b.

Note that the plug V1a corresponds to the via portion electrically coupling the respective coupled portions (i.e., terminal TE3) of the coils (CL2a and CL2b) to the lead-out wire HW1. Also, the center line extending through the coil pattern (i.e., coil CL2) including the series-coupled coils CL2a and CL2b corresponds to the foregoing line SL1 (see FIG. 23 described above). In each of FIGS. 32 to 35, the line SL1 is shown as the dot-dash line. The line B4-B4 in each of FIGS. 14 and 15 corresponds to the line SL1 in plan view.

In the case where the series-coupled coils CL2a and CL2b are provided with two-dimensional shapes which are line-symmetric to each other in plan view, by disposing the plug V1a electrically coupling the coil wire CW3 to the lead-out wire HW1 on the line SL1 (i.e., on the line B4-B4) as in FIGS. 14 and 15, it is possible to allow the capacitance (coupling capacitance) between the coils CL2a and CL1 and the capacitance (coupling capacitance) between the coils CL2b and CL1 to have substantially equal values. This allows the differential operation to be more appropriately performed.

In the case in the first modification in FIGS. 32 and 33 and in the case in the second modification in FIGS. 34 and 35, the plug V1a (via portion) is disposed at a position displaced from the center line (corresponding to the line SL1) extending through the center of the coil pattern (i.e., coil CL2) including the series-coupled coils CL2a and CL2b in plan view.

There may also be a case where, to allow the capacitance between the coils CL2a and CL1 and the capacitance between the coils CL2b and CL1 to have substantially equal values, depending on the respective two-dimensional shapes of the coils CL2a and CL2b, the position of the plug V1a electrically coupling the coil wire CW3 to the lead-out wire HW1 should be displaced from the line SL1. In such a case, e.g., the respective positions of the lead-out wire HW1 and the plug V1a can be displaced leftwardly of the line SL1 (to the left side in FIGS. 32 and 33) as in the first modification in FIGS. 32 and 33 or rightwardly of the line SL1 (to the right side in FIGS. 34 and 35) as in the second modification in FIGS. 34 and 35). This allows the capacitance (coupling capacitance) between the coils CL2a and CL1 and the capacitance (coupling capacitance) between the coils CL2b and CL1 to have substantially equal values and allows the differential operation to be more appropriately performed.

<About Example of Configuration of Semiconductor Package>

Next, a description will be given of an example of a configuration of a semiconductor package using the semiconductor device (semiconductor chip CP) in the present embodiment. The semiconductor chip CP can be regarded as the semiconductor device. Alternatively, the semiconductor package in which the semiconductor chip is embedded can also be regarded as the semiconductor device.

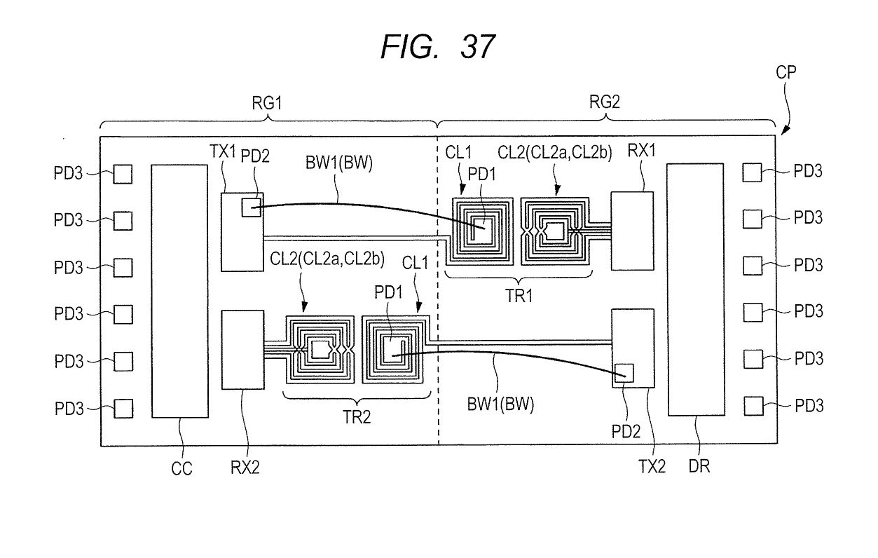

FIG. 36 is a cross-sectional view showing a semiconductor package (semiconductor device) PKG in the present embodiment. FIG. 37 is a plan view showing an example of the chip layout of the foregoing semiconductor chip CP embedded in the semiconductor package PKG. Note that, for improved clarity of illustration, in each of the transformer s TR1 and TR2 shown in FIG. 37, the primary coil CL1 and the secondary coil CL2 (CL2a and CL2b) are displaced from each other. However, in an actual situation, in each of the transformer s TR1 and TR2, the primary coil CL1 and the secondary coil CL2 (CL2a and CL2b) overlap each other in plan view. Also, in FIG. 37, the wires BW1 described later are shown, but wires BW2 described later are not shown.

The semiconductor package PKG shown in FIG. 36 includes the foregoing semiconductor chip CP. The following will specifically describe a configuration of the semiconductor package PKG.

The semiconductor package PKG shown in FIG. 36 has the semiconductor chip CP, a die pad DP over which the semiconductor chip CP is mounted, a plurality of leads LD made of a conductor, a plurality of bonding wires (hereinafter referred to as wires) BW as a conductive coupling member, and a sealing resin portion MR sealing the semiconductor chip CP, the die pad DP, the leads LD, and the bonding wires BW.

The sealing resin portion (sealing portion, sealing resin, or sealing body) MR is made of a resin material such as, e.g., a thermosetting resin material and can also contain a filler or the like. By the sealing resin portion MR, the semiconductor chip CP, the die pad DP, the plurality of leads LD, and the plurality of wires BW are sealed and electrically and mechanically protected. The two-dimensional shape (outer shape) of the sealing resin portion MR which crosses the thickness thereof can be, e.g., a rectangle (quadrilateral).

Over the top surface of the semiconductor chip CP as the main surface thereof where the elements are famed, the plurality of pads (pad electrodes or bonding pads) PD are formed. Each of the pads PD of the semiconductor chip CP is electrically coupled to the circuits or elements foiled in the semiconductor chip CP. Note that, of the semiconductor chip CP, the main surface where the pads PD are formed is referred to as the top surface of the semiconductor chip CP and the main surface thereof opposite to the top surface is referred to as the back surface of the semiconductor chip CP.

The plurality of pads PD of the semiconductor chip CP include pads PD1, PD2, and PD3. The semiconductor chip CP has the pad PD1 for the transformer TR1, the pad PD1 for the transformer TR2, the pad PD2 for the transmission circuit TX1, the pad PD2 for the transmission circuit TX2, and the plurality of pads PD3.

In the semiconductor chip CP, the pad PD1 for the transformer TR1 is disposed inside the foregoing coil CL1 for the transformer TR1 and electrically coupled to one end of the foregoing coil CL1 for the transformer TR1. Also, in the semiconductor chip CP, the pad PD1 for the transformer TR2 is disposed inside the foregoing coil CL1 for the transformer TR2 and electrically coupled to one end of the foregoing coil CL1 for the transformer TR2.

The pad PD2 for the transmission circuit TX1 is electrically coupled to the foregoing transmission circuit TX1 via the internal wiring of the semiconductor chip CP. Also, the pad PD2 for the transmission circuit TX2 is electrically coupled to the foregoing transmission circuit TX2 via the internal wiring of the semiconductor chip CP.

Each of the plurality of pads PD3 of the semiconductor chip CP is electrically coupled to the foregoing control circuit CC or the foregoing control circuit DR via the internal wiring of the semiconductor chip CP.

The semiconductor chip CP is mounted (placed) over the upper surface of the die pad DP as a chip mounting portion such that the top surface of the semiconductor chip CP faces upward. The back surface of the semiconductor chip CP is bonded and fixed to the upper surface of the die pad DP via a die bonding material (adhesive) DB.

The leads LD are famed of a conductor and preferably made of a metal material such as copper (Cu) or a copper alloy. Each of the leads LD includes an inner lead portion as the portion of the lead LD which is located in the sealing resin portion MR and an outer lead portion as the portion of the lead LD which is located outside the sealing resin portion MR. The outer lead portions of the leads LD protrude from the side surfaces of the sealing resin portion MR to the outside of the sealing resin portion MR. The spaces between the respective inner lead portions of the adjacent leads LD are filled with the material forming the sealing resin portion MR. The respective outer lead portions of the leads LD can function as the external coupling terminals (external terminals) of the semiconductor package PKG. The respective outer lead portions of the leads LD are bent such that the lower surfaces of the outer lead portions in the vicinity of the end portions thereof are located slightly below the lower surface of the sealing resin portion MR.

Each of the pads PD3 of the semiconductor chip CP is electrically coupled to the inner lead portion of any of the leads LD via any of the wires BW. That is, to each of the pads PD3, one end of the wire BW is coupled while, the other end of the wire BW is coupled to the inner lead portion of the lead LD.

The pad PD1 for the transformer TR1 of the semiconductor chip CP is electrically coupled to the pad PD2 for the transmission circuit TX1 via the wire BW. That is, to the pad PD1 for the transformer TR1, one end of the wire BW is coupled, while the other end of the wire BW is coupled to the pad PD2 for the transmission circuit TX1.

Also, the pad PD1 for the transformer TR2 of the semiconductor chip CP is electrically coupled to the pad PD2 for the transmission circuit TX2 via the wire BW. That is, to the pad PD1 for the transformer TR2, one end of the wire BW is coupled, while the other end of the wire BW is coupled to the pad PD2 for the transmission circuit TX2.

Note that the wires BW electrically coupling the pads PD1 and PD2 to each other are denoted by a reference numeral BW1 and referred to as the wires BW1 and the wires BW electrically coupling the pads PD3 to the leads LD are denoted by a reference numeral BW2 and referred to as the wires BW 2.

Thus, the plurality of wires BW included in the semiconductor package PKG include the plurality of wires BW2 electrically coupling the plurality of pads PD3 to the plurality of leads LD, the wire BW1 electrically coupling the pad PD1 for the transformer TR1 to the pad PD2 for the transmission circuit TX1, and the wire BW1 electrically coupling the pad PD1 for the transformer TR2 to the pad PD2 for the transmission circuit TX2.

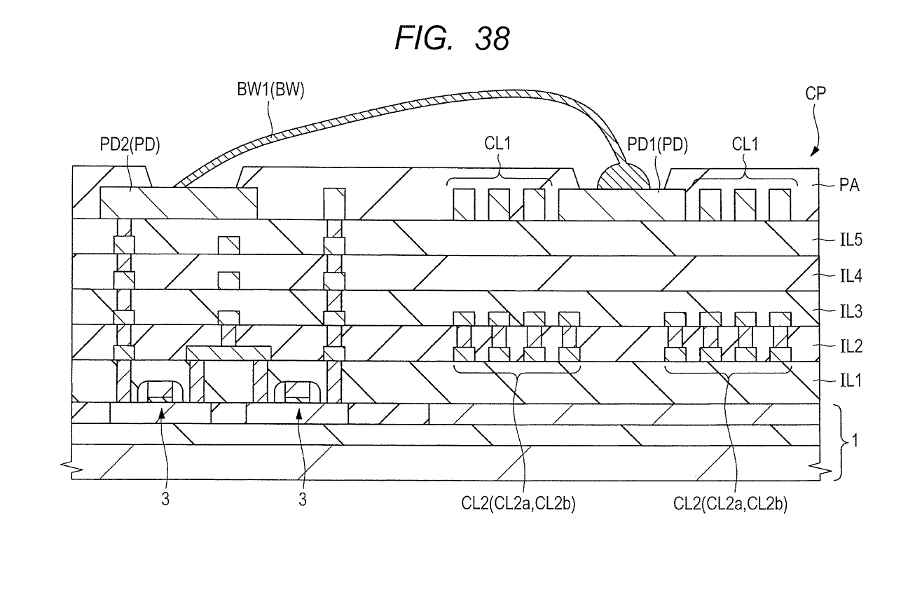

FIG. 38 is a cross-sectional view showing a part of the semiconductor package PKG, which shows a cross section corresponding to FIG. 3 described above. In FIG. 38, the semiconductor chip CP and the wires BW1 are shown, but the illustration of the die bonding material DB, the die pad DP, and the sealing resin portion MR is omitted. FIG. 38 shows a state where the pad PD1 disposed inside the coil CL1 is electrically coupled via the wire BW1 to the pad PD2 electrically coupled to the transmission circuit via the internal wire.

Each of the wires BW is a conductive coupling member. More specifically, the wire BW is a conductive wire and made of a thin metal wire such as, e.g., a gold (Au) wire or a copper (Cu) wire. The wires BW are sealed in the sealing resin portion MR and are not exposed from the sealing resin portion MR.

Note that, as described above, the transmission circuit TX1 and the transformer TR2 are disposed in the foregoing lower-voltage circuit region RG1, while the transmission circuit TX2 and the transformer TR1 are disposed in the foregoing higher-voltage circuit region RG2. As a result, in the semiconductor chip CP, the pad PD2 for the transmission circuit TX1 is disposed in the foregoing lower-voltage circuit region RG1, the pad PD1 for the transformer TR1 is disposed in the foregoing higher-voltage circuit region RG2, the pad PD2 for the transmission circuit TX2 is disposed in the foregoing higher-voltage circuit region RG2, and the pad PD1 for the transformer TR2 is disposed in the foregoing lower-voltage circuit region RG1.

Consequently, one end of the primary coil (coil CL1) of the transformer TR1 is electrically coupled to the transmission circuit TX1 via the wire BW1 coupling the pad PD1 for the transformer TR1 to the pad PD2 for the transmission circuit TX1 and via the internal wiring coupling the pad PD2 for the transmission circuit TX1 to the transmission circuit TX1. The other end of the primary coil (coil CL1) of the transformer TR1 is electrically coupled to the transmission circuit TX1 via the internal wiring of the semiconductor chip CP. Also, the secondary coil (coil CL2a or CL2b) of the transformer TR1 is electrically coupled to the reception circuit RX1 via the internal wiring of the semiconductor chip CP.

On the other hand, one end of the primary coil (coil CL1) of the transformer TR2 is electrically coupled to the transmission circuit TX2 via the wire BW1 coupling the pad PD1 for the transformer TR2 to the pad PD2 for the transmission circuit TX2 and via the internal wiring coupling the pad PD2 for the transmission circuit TX2 to the transmission circuit TX2. The other end of the primary coil (coil CL1) of the transformer TR2 is electrically coupled to the transmission circuit TX2 via the internal wire of the semiconductor chip CP. Also, the secondary coil (coils CL2a and CL2b) of the transformer TR2 is electrically coupled to the reception circuit RX2 via the internal wiring of the semiconductor chip CP.

For example, the semiconductor package PKG can be manufactured as follows. Specifically, first, a lead frame in which the die pad DP and the plurality of leads LD are connected to a frame body is provided. By performing a die bonding step, the semiconductor chip CP is mounted over the die pad DP of the lead frame via the die bonding material DB to be bonded thereto. Then, a wire bonding step is performed. Thus, the plurality of pads PD3 of the semiconductor chip CP are electrically bonded to the plurality of leads LD via the plurality of wires BW. Also, each of the pads PD1 of the semiconductor chip is electrically coupled to the corresponding pad PD2 via the corresponding wire BW. Then, by performing a resin sealing step, the sealing resin portion MR is famed to seal the semiconductor chip CP, the die pad DP, the plurality of leads LD, and the plurality of wires BW. Subsequently, the plurality of leads LD having the respective inner lead portions sealed in the sealing resin portion MR are cut and separated from the frame body of the lead frame. Then, the outer lead portions of the plurality of leads LD are subjected to bending. In this manner, the semiconductor package PKG can be manufactured.

A description will be given herein of examples of the applications of a product in which the semiconductor package PKG is mounted. The examples of the applications include the motor controller of an automobile or an electric household appliance such as a clothes washer, a switching power supply, a lighting controller, a solar power generation controller, a mobile phone, a mobile communication device, and the like.

For example, in an automotive application, the power supply voltage supplied to the circuit (control circuit CC) in the lower-voltage circuit region RG1 of the semiconductor chip CP is about 5 V. On the other hand, a power supply voltage for a target switch to be driven by the control circuit (drive circuit) DR is a high voltage of, e.g., 600 V to 1000 V or higher. When the switch is turned ON, the high voltage can be supplied to the higher-voltage circuit region RG2 of the semiconductor chip CP.

The description has been given heretofore of the case where the package foam of the semiconductor package PKG is a SOP (Small Outline Package). However, the present invention is also applicable to a semiconductor package other than the SOP.

While the invention achieved by the present inventors has been specifically described heretofore on the basis of the embodiment thereof, the present invention is not limited to the foregoing embodiment. It will be appreciated that various changes and modifications can be made in the invention within the scope not departing from the gist thereof.

What is claimed is:

1. A semiconductor device, comprising:
a semiconductor substrate;
a wiring structure formed over the semiconductor substrate and including a plurality of wiring layers; and
a first coil, a second coil, and a third coil which are formed above the semiconductor substrate,
wherein, in a region located under the first coil and overlapping the first coil in plan view, the second and third coils are disposed,
wherein the second and third coils are famed in the same layer and electrically coupled in series to each other, and
wherein each of the second and third coils and the first coil are not coupled to each other via a conductor, but are magnetically coupled to each other.

2. The semiconductor device according to claim 1,
wherein the first coil is formed of one of the wiring layers.

3. The semiconductor device according to claim 2,
wherein the first coil does not have portions crossing each other in plan view.

4. The semiconductor device according to claim 3,
wherein the first coil is formed of the uppermost one of the wiring layers.

5. The semiconductor device according to claim 4, wherein, inside the first coil in plan view, a pad electrode coupled to one end of the first coil is disposed.

6. The semiconductor device according to claim 2,
wherein each of the second and third coils is formed of two of the wiring layers.

7. The semiconductor device according to claim 6,
wherein the second and third coils have respective crossing portions which cross each other in plan view.

8. The semiconductor device according to claim 7,
wherein, in the crossing portions, the second coil is foiled only of one of the two wiring layers and the third coil is formed only of the other of the two wiring layers.

9. The semiconductor device according to claim 7,
wherein the second and third coils are wound in opposite directions.

10. The semiconductor device according to claim 7,
wherein the second and third coils have two-dimensional shapes which are line-symmetrical to each other in plan view.

11. The semiconductor device according to claim 6,
wherein, to respective portions of the second and third coils which are coupled to each other, a lead-out wire in a layer located below the two wiring layers is electrically coupled.

12. The semiconductor device according to claim 11,
wherein, from the lead-out wire, a fixed potential is supplied to the coupled portions.

13. The semiconductor device according to claim 11,
wherein the second and third coils are respectively formed of the lowermost one of the wiring layers and the one of the wiring layers which is located immediately above the lowermost wiring layer.

14. The semiconductor device according to claim 13, further comprising:
a MISFET formed over the semiconductor substrate,
wherein the lead-out wire is made of a conductive pattern in the same layer as that of a gate electrode of the MISFET.

15. The semiconductor device according to claim 11,
wherein the coupled portions are electrically coupled to the lead-out wire via a via portion.

16. The semiconductor device according to claim 15,
wherein, in plan view, the via portion is disposed on a center line extending through a center of a coil pattern including the second and third coils coupled in series to each other.

17. The semiconductor device according to claim 15,
wherein, in plan view, the via portion is disposed at a position displaced from a center line extending through a center of a coil pattern including the second and third coils coupled in series to each other.

18. The semiconductor device according to claim 1,
wherein the first coil is a primary coil and each of the second and third coils is a secondary coil.
